(19) United States
(12) Patent Application Publication
(10) Pub. No.: US 2026/0324364 A1
(43) Pub. Date: Oct. 15, 2026

(54) METHOD OF DETERMINING OR PREDICTING STATE OF CHAMBER, METHOD OF CORRECTING MEASUREMENT ERROR FOR CHAMBER, AND APPARATUS FOR MONITORING STATE OF CHAMBER

(71) Applicant: AETHER, INC., Daejeon (KR)

(72) Inventors: Inshik BAE, Daejeon (KR); Sang Won LEE, Daejeon (KR); Jaehyun KIM, Daejeon (KR)

(21) Appl. No.: 19/688,580

(22) Filed: May 27, 2026

Related U.S. Application Data
(63) Continuation of application No. PCT/KR2024/021012, filed on Dec. 24, 2024.

(30) Foreign Application Priority Data
Jan. 3, 2024 (KR) 10-2024-0000631
Jan. 3, 2024 (KR) 10-2024-0000632
Dec. 20, 2024 (KR) 10-2024-0192489

(51) Int. Cl. H10P 74/00

(52) U.S. Cl. CPC H10P 74/23

(57) ABSTRACT

The present disclosure discloses a method of monitoring the state of a chamber by a chamber monitoring device. The method may include: measuring the state of the chamber to generate a plurality of state data; calculating similarities between each of the plurality of state data and the reference state data to obtain a plurality of pieces of state similarity data; matching the plurality of pieces of state similarity data with process section data for sections in which each of the plurality of processes is performed to obtain a plurality of state similarity patterns; and determining whether the chamber is operating normally or predicting a time point at which the chamber is abnormally operated using two or more state similarity patterns.

### CROSS-REFERENCE TO RELATED APPLICATIONS

This is a bypass continuation of International PCT Application No. PCT/KR2024/021012, filed on Dec. 24, 2024, which claims priority to Republic of Korea Patent Application No. 10-2024-0000631, filed on Jan. 3, 2024, Republic of Korea Patent Application No. 10-2024-0000632, filed on Jan. 3, 2024, and Republic of Korea Patent Application No. 10-2024-0192489, filed on Dec. 20, 2024, which are incorporated by reference herein in their entirety.

### BACKGROUND OF THE INVENTION

### Field of the Invention

The present disclosure relates to a method of determining or predicting a state of a chamber, a method of correcting a measurement error for the chamber, and an apparatus therefor.

Specifically, the present disclosure relates to a method of predicting whether a chamber is broken, aging, or needs replacement of parts, etc., and/or time points of failure, aging, replacement of parts, etc. In addition, the present disclosure relates to a method of correcting measurement errors that may occur while attaching and/or detaching a monitoring device to/from a chamber and/or measurement errors that may occur when measurements are performed in different chambers.

### Description of the Related Art

In the manufacturing and inspection process of the semiconductors or displays, it is important to check whether the state of equipment for the process is within the verified normal range and whether process conditions are properly set. However, although the process state may be partially checked in a such manner as to detect a specific physical quantity of plasma, it is difficult to directly check whether the equipment is properly assembled before the process or whether there is an abnormality in the condition of the equipment during the process. In the end, a test run must be conducted to check the results in the process, which leads to additional costs and time. In addition, even when the process results are incorrect, it is difficult to find the cause of the problem.

In addition, such a method of conducting the test run to check the process results may only monitor the current state of the equipment and cannot predict the extent to which the equipment is aging or the time point at which at least one part of the equipment will fail.

However, when the equipment is found to have failed, it may cause a manufacturing process such as semiconductor or display manufacturing to be interrupted for several days or even several months, which leads to a fatal delay in the production schedule and an unexpected decrease in production volume. In addition, in order to accurately determine the time points of aging and failure of the equipment, it is also very important to reduce the measurement error when measuring the condition of the equipment.

### SUMMARY OF THE INVENTION

The present disclosure may provide a method of determining whether a chamber is aging and failing.

The present disclosure may provide a method of predicting the aging and failing time point of a chamber.

The present disclosure may provide a method of reducing measurement errors when performing state measurements multiple times for one chamber.

The present disclosure may provide a method of reducing measurement errors when measuring the states of a plurality of chambers.

Technical problems to be solved by the present disclosure are not limited to the aforementioned technical problems, and other technical problems which are not mentioned will be clearly understood by those skilled in the art from the present disclosure.

According to an embodiment of the present disclosure, a method of monitoring a state of a chamber by a chamber monitoring apparatus, wherein a process cycle including a plurality of processes is performed one or more times in the chamber, the method comprising: obtaining a reference state data for monitoring the state of the chamber, wherein the reference state data is a first reference state data of the chamber measured in IDLE duration of the chamber or a second reference state data of the chamber measured in a duration corresponding to one of the plurality of processes; transmitting radio waves in a specific frequency range into an inside of the chamber M times and receiving reflected radio waves from the inside of the chamber M times, wherein M is natural number and is equal or larger than 2; generating a plurality of third state data by measuring the state of the chamber based on the received radio waves M times; calculating similarities between each of the plurality of third state data and the reference state data and obtaining a plurality of pieces of state similarity data using the similarities; obtaining a plurality of state similarity patterns configured in unit of the process cycle by matching process duration data for durations in which each of the plurality of processes is performed and the plurality of pieces of state similarity data; and determining whether the chamber is performed in a normal operation or predicting when the chamber will be entered in an abnormal operation using two or more state similarity patterns among the plurality of state similarity patterns.

According to the present disclosure, a chamber monitoring apparatus of monitoring a state of the chamber, wherein a process cycle including a plurality of processes is performed one or more times in the chamber, the chamber monitoring apparatus comprising: an antenna configured to transmit radio waves in a specific frequency range into an inside of the chamber and receive reflected radio waves from the inside of the chamber; a bracket configured to fix the antenna to an outside of the chamber; a signal processor configured to apply an electrical signal to the antenna and obtain an electrical signal from the antenna; and a controller configured to control the signal processor and generate a state data of the chamber based on the obtained electrical signal, wherein the controller is configured to: obtain a reference state data for monitoring the state of the chamber, wherein the reference state data is a first reference state data of the chamber measured in IDLE duration of the chamber or a second reference state data of the chamber measured in a duration corresponding to one of the plurality of processes, control the signal processor, such that the antenna transmits radio waves M times and receive radio waves M times, to obtain electrical signals according to the received radio waves, wherein M is natural number and is equal or larger than 2, generate a plurality of third state data by measuring the state of the chamber based on the electrical signals, calculate similarities between each of the plurality of third state data and the reference state data and obtain a plurality of pieces of state similarity data using the similarities, obtain a plurality of state similarity patterns configured in unit of the process cycle by matching a process duration data for durations in which each of the plurality of processes is performed and the plurality of pieces of state similarity data, and determine whether the chamber is performed in a normal operation or predicting when the chamber will be entered in an abnormal operation using two or more state similarity patterns among the plurality of state similarity patterns.

According to an embodiment of the present disclosure, a method of determining error correction function for correcting measurement error between parameter sets caused by an installation and removal of a chamber monitoring apparatus using P chamber monitoring apparatuses, wherein P is natural number and is equal to or greater than 1 and the parameter sets is one among (i) S-parameter set, (ii) H-parameter set, (iii) Y-parameter set, (iv) Z-parameter set and (v) parameter set induced from one of S-parameter set, H-parameter set, Y-parameter set and Z-parameter set, the method comprising: generating a reference parameter set of a chamber by transmitting radio waves in a specific frequency range to an inside of the chamber after installing a first chamber monitoring apparatus, among the P chamber monitoring apparatuses, within a first region of outside of the chamber in a first process state; generating L first parameter sets by repeatedly performing a first operation N times for each of the P chamber monitoring apparatuses, wherein N is equal to or greater than 2 and L is P multiplied by N; determining a first learning model including a plurality of first error correction parameters; updating the plurality of first error correction parameters to a plurality of second error correction parameters by repeatedly performing a second operation until difference information between the reference parameter set and an output parameter set is included in a predetermined range, wherein the output parameter set is obtained by inputting one of the L first parameter sets to the first learning model; and determining a second learning model including the plurality of second error correction parameters as the error correction function, wherein the second operation comprising: obtaining a first output parameter set by inputting a first parameter set of the L first parameter sets to the first learning model, wherein the first parameter set is not input to the first learning model previously, and obtaining a first difference information between the reference parameter set and the first output parameter set and modifying the plurality of first error correction parameters based on the first difference information, wherein the first operation comprising: removing a chamber monitoring apparatus from the chamber, re-installing the chamber monitoring apparatus within the first region and transmitting radio waves in the specific frequency range to the inside of the chamber, wherein the chamber is in the first process state, and receiving radio waves reflected from the inside of the chamber and generating a first parameter set based on the received radio waves.

According to an embodiment of the present disclosure, a method of determining error correction function for correcting measurement error between parameter sets corresponding to each of a plurality of chambers using P chamber monitoring apparatuses, wherein P is natural number and is equal to or greater than 1 and the parameter sets is one among (i) S-parameter set, (ii) H-parameter set, (iii) Y-parameter set, (iv) Z-parameter set and (v) parameter set induced from one of S-parameter set, H-parameter set, Y-parameter set and Z-parameter set, the method comprising: generating a reference parameter set of a first chamber by transmitting radio waves in a specific frequency range to an inside of the first chamber after installing a first chamber monitoring apparatus, among the P chamber monitoring apparatuses, within a first region of outside of the chamber in a first process state; generating L first parameter sets by repeatedly performing a first operation N times for each of the P chamber monitoring apparatuses, wherein N is equal to or greater than 2 and L is P multiplied by N; determining a first learning model including a plurality of first error correction parameters; updating the plurality of first error correction parameters to a plurality of second error correction parameters by repeatedly performing a second operation until difference information between the reference parameter set and an output parameter set is included in a predetermined range, wherein the output parameter set is obtained by inputting one of the L first parameter sets to the first learning model; and determining a second learning model including the plurality of second error correction parameters as the error correction function, wherein the second operation comprising: obtaining a first output parameter set by inputting a first parameter set of the L first parameter sets to the first learning model, wherein the first parameter set is not input to the first learning model previously; and obtaining a first difference information between the reference parameter set and the first output parameter set and modifying the plurality of first error correction parameters based on the first difference information, wherein the first operation comprising: installing a chamber monitoring apparatus to a first regions of a second chamber selected among the plurality of the chambers and transmitting radio waves in the specific frequency range to the inside of the second chamber, wherein the second chamber is in the first process state and the second chamber is not selected previously among the plurality of the chambers; receiving radio waves reflected from the inside of the chamber and generating a first parameter set based on the received radio waves.

According to an embodiment of the present disclosure, a method of determining error correction function for correcting measurement error between parameter sets caused by an installation and removal of a chamber monitoring apparatus and measurement error between parameter sets corresponding to each of Q chambers using P chamber monitoring apparatuses, wherein P is natural number and is equal to or greater than 1, Q is natural number is equal to or greater than 2, and the parameter sets is one among (i) S-parameter set, (ii) H-parameter set, (iii) Y-parameter set, (iv) Z-parameter set and (v) parameter set induced from one of S-parameter set, H-parameter set, Y-parameter set and Z-parameter set, the method comprising: generating a reference parameter set of a first chamber by transmitting radio waves in a specific frequency range to an inside of the first chamber after installing a first chamber monitoring apparatus, among the P chamber monitoring apparatuses, within a first region of outside of the chamber in a first process state; generating L first parameter sets by repeatedly performing a first operation Q times for each of the P chamber monitoring apparatuses, wherein Q is equal to or greater than 2, the first operation is that a third operation is repeatedly performed N times for each of the Q chambers and L is a product of P, Q and N; determining a first learning model including a plurality of first error correction parameters; updating the plurality of first error correction parameters to a plurality of second error correction parameters by repeatedly performing a second operation until difference information between the reference parameter set and an output parameter set is included in a predetermined range, wherein the output parameter set is obtained by inputting one of the L first parameter sets to the first learning model; and determining a second learning model including the plurality of second error correction parameters as the error correction function, wherein the second operation comprising: obtaining a first output parameter set by inputting a first parameter set of the L first parameter sets to the first learning model, wherein the first parameter set is not input to the first learning model previously; and obtaining a first difference information between the reference parameter set and the first output parameter set and modifying the plurality of first error correction parameters based on the first difference information, wherein the third operation comprising: removing a chamber monitoring apparatus from the chamber and re-installing the chamber monitoring apparatus in the first region and transmitting radio waves in the specific frequency range to the inside of the chamber, wherein the chamber is in the first process state; and receiving radio waves reflected from the inside of the chamber and generating a first parameter set based on the received radio waves.

According to the present disclosure, the state of the chamber may be monitored at low cost and time by transmitting radio waves into the inside of the chamber and receiving and radio waves reflected from the inside of the chamber to be analyzed.

According to the present disclosure, the accuracy of chamber state monitoring measurement may be increased by reducing the measurement error that may occur while monitoring the state of each chamber by repeatedly attaching and detaching the monitoring device to/from at least one chamber at least once.

The effect of the present disclosure is not limited to the above-mentioned effect, other effects which are not mentioned will be clearly understood by those skilled in the art from the present disclosure.

### BRIEF DESCRIPTION OF THE DRAWINGS

FIG. 1 is a block diagram illustrating a monitoring device according to an embodiment.

FIGS. 2 and 3 are schematic diagrams illustrating a monitoring device installed at a chamber according to an embodiment.

FIG. 4 is a graph illustrating S11 parameter that is an example of state data.

FIG. 5 is a flowchart illustrating a method of generating reference state data according to an embodiment.

FIG. 6 is a flow chart illustrating a method of calculating the similarity between reference state data and state data.

FIG. 7 is a graph illustrating measured similarity values according to the present disclosure.

FIG. 8 is a flow chart illustrating a method of calculating a similarity pattern to predict a time of an abnormal operation of a chamber or determine whether the chamber is operating normally, according to the present disclosure.

FIG. 9 is a diagram illustrating a method of determining a similarity pattern by matching process data and a similarity graph.

FIG. 10 is a diagram illustrating a method of determining a similarity pattern according to an embodiment of the present disclosure.

FIG. 11 is a diagram illustrating a method of predicting a time of an abnormal operation of a chamber according to an embodiment of the present disclosure.

FIG. 12 and FIG. 13 are diagrams illustrating a method of determining whether a chamber is operating normally according to an embodiment of the present disclosure.

FIG. 14 is a diagram illustrating the consistency between a result of determining whether the chamber is operating normally and an actual result on whether the chamber is operating normally, according to an embodiment of the present disclosure.

FIGS. 15 to 17 are diagrams illustrating the consistency between a predicted time when the chamber is operating abnormally and an actual time when the chamber is operating abnormally, according to an embodiment of the present disclosure.

FIGS. 18 to 19 are diagrams illustrating another embodiment of determining abnormal operation of a chamber.

FIGS. 20 to 22 are diagrams illustrating another embodiment of predicting a time of abnormal operation of a chamber.

FIGS. 23 to 26 are diagrams illustrating measurement errors that occur when attaching and/or detaching a monitoring device to at least one chamber.

FIG. 27 is a drawing illustrating examples of learning models that may be used for measurement error correction according to the present disclosure.

FIG. 28 to FIG. 31 are diagrams illustrating a method of generating an error correction function according to an embodiment of the present disclosure.

FIG. 32 to FIG. 36 are diagrams illustrating a method of generating chamber monitoring information after correcting an error of state data using an error correction function and an error correction result thereof.

FIG. 37 is a block diagram illustrating a monitoring system according to an embodiment.

FIG. 38 is a schematic diagram illustrating a monitoring system installed in process equipment, according to an embodiment.

### DETAILED DESCRIPTION

Embodiments described in the present disclosure are for clearly describing the idea of the present disclosure to those skilled in the art to which the present disclosure belongs, so the present disclosure is not limited to the embodiments described in the present disclosure and the scope of the present disclosure should be construed as including modifications or variations that are within the idea of the present disclosure.

As the terms used in the present disclosure, general terms currently widely used are used considering functions in the present disclosure. However, the terms may vary according to the intentions of those skilled in the art, precedents, or the emergence of new technology. However, unlike this, when a particular term is used defined as having an optional meaning, the meaning of the term will be described. Thus, the terms used in the present disclosure should be construed based on the actual meanings of the terms and details throughout the present disclosure rather than simply the names of the terms.

The drawings accompanying the present disclosure are for easily describing the present disclosure, and the shapes shown in the drawings may be exaggerated to help the understanding of the present disclosure, so the present disclosure is not limited by the drawings.

In the present disclosure, if it is decided that a detailed description of known configuration or function related to the present disclosure makes the subject matter of the present disclosure unclear, the detailed description is omitted. In addition, throughout the present disclosure, the terms first, second, and so on are used only to distinguish from one element to another, unless otherwise noted.

According to the present disclosure, a monitoring device may be provided. The monitoring device transmits radio waves to inside a chamber of process equipment, such as semiconductor process equipment and display process equipment, and receives radio waves reflected by the internal space of the chamber, thereby monitoring a geometrical status of the internal space of the chamber. More specifically, the chamber includes a plurality of parts, for example, a lower electrode on which a substrate, such as a wafer, is placed, an upper electrode facing the lower electrode, pins for supporting a substrate, and a baffle. The geometrical status of the chamber may be defined by a combination of geometrical statuses, such as positions or shapes, of the respective parts.

Alternatively, for example, as plasma is generated inside the chamber, the load inside the chamber may change, or as the process cycle progresses in the chamber, the environment inside the chamber may change according to each process. Herein, the monitoring device can monitor the electrical characteristics according to the changing load or environment inside the chamber.

Herein, even if the same radio waves are transmitted to inside the chamber, the received radio waves may vary depending on the geometrical status of the chamber. For example, in the case in which the geometrical status of a portion of the parts is changed, for example, the position or shape of the portion of the parts is changed, even if the same radio waves are transmitted to inside the chamber, the radio waves received after change may be different from the radio waves received before change. That is, how radio waves are reflected by the internal space of the chamber may vary depending on the geometrical status of the chamber. In other words, the received reflected waves may reflect the geometrical status of the chamber.

Accordingly, the monitoring device is capable of monitoring the chamber in which a process is not in progress (as well as the chamber in which a process is in progress). For example, the monitoring device may monitor the geometrical status of the internal space of the chamber to monitor the chamber in which a process is not in progress, such as determining an assembly status of process equipment when the process equipment is manufactured, or determining a result of preventive maintenance (PM) of process equipment. As another example, the monitoring device monitors the geometrical status of the internal space of the chamber to monitor the chamber in which a process is in progress, such as proceeding a process while checking each process step proceeds normally, or predicting the timing of preventive maintenance.

The device and the method for monitoring a status of a chamber disclosed herein monitor whether equipment is properly assembled before a process starts, or whether the status of equipment is normal between processes and during a process, as described above. That is, the objects to be monitored by the device and the method disclosed herein may include the geometrical shape of each of the parts inside the chamber, a level of wear-out of each of the parts, the relative positional relationship between each of the parts, unnecessary deposition of by-products generated by the process of the target substrate through the chamber on the inner wall of the chamber and the surface of each part inside the chamber, etc. On the other hand, the objects to be monitored by the device and the method disclosed herein may not include material supplied into the chamber to be monitored and state of energy (for example, active species, etching gas, inert gas flowing into the chamber to perform the necessary process, RF power or their plasma, etc).

A method, according to an embodiment of the present disclosure, of monitoring a state of a chamber by a chamber monitoring apparatus, wherein a process cycle including a plurality of processes is performed one or more times in the chamber, comprises: obtaining a reference state data for monitoring the state of the chamber, wherein the reference state data is a first reference state data of the chamber measured in IDLE duration of the chamber or a second reference state data of the chamber measured in a duration corresponding to one of the plurality of processes; transmitting radio waves in a specific frequency range into an inside of the chamber M times and receiving reflected radio waves from the inside of the chamber M times, wherein M is natural number and is equal or larger than 2; generating a plurality of third state data by measuring the state of the chamber based on the received radio waves M times; calculating similarities between each of the plurality of third state data and the reference state data and obtaining a plurality of pieces of state similarity data using the similarities; obtaining a plurality of state similarity patterns configured in unit of the process cycle by matching process duration data for durations in which each of the plurality of processes is performed and the plurality of pieces of state similarity data; and determining whether the chamber is performed in a normal operation or predicting when the chamber will be entered in an abnormal operation using two or more state similarity patterns among the plurality of state similarity patterns.

Furthermore, the chamber monitoring apparatus predicting when the chamber will be entered in the abnormal operation comprises: selecting two or more state similarity data among the plurality of pieces of state similarity data, wherein a state similarity data corresponding to a first process is selected in each of the plurality of state similarity patterns; determining a function for predicting the abnormal operation based on the two or more state similarity data, wherein the function is determined based on a time variable; and predicting, as a time of the abnormal operation of the chamber, a first time that a result value of the function calculated according to the time variable is equal to or smaller than a preconfigured similarity threshold.

Furthermore, the chamber monitoring apparatus predicting when the chamber will be entered in the abnormal operation is repeatedly performed at each time when the state similarity pattern is additionally obtained.

Furthermore, the chamber monitoring apparatus determines whether the chamber is performed in the normal operation comprises: selecting a first state similarity pattern lastly obtained among the plurality of state similarity patterns; selecting a second state similarity pattern, different the first state similarity pattern, among the plurality of state similarity patterns; calculating difference values between the first state similarity pattern and the second state similarity pattern according to each process and a corresponding time in the each process; and determining that the chamber is operated in abnormal in a process corresponding to a difference value exceeding a preconfigured similarity threshold among the difference values.

Furthermore, the chamber monitoring apparatus determining whether the chamber is performed in the normal operation comprises: determining the preconfigured similarity threshold according to an interval between the first state similarity pattern and the second state similarity pattern within the plurality of state similarity patterns.

Furthermore, the chamber monitoring apparatus calculating difference values between the first state similarity pattern and the second state similarity pattern comprises: adjusting state similarity data of the first state similarity pattern based on state similarity data of the second state similarity pattern; and calculating difference values between the adjusted state similarity data of the first state similarity pattern and the state similarity data of the second state similarity pattern.

Furthermore, the chamber monitoring apparatus adjusting state similarity data of the first state similarity pattern comprises: selecting two or more state similarity data among the plurality of pieces of state similarity data, wherein a state similarity data corresponding to a first process is selected in each of the plurality of state similarity patterns; determining a function for predicting the abnormal operation based on the two or more state similarity data, wherein the function is determined based on a time variable; and adjusting the state similarity data of the first state similarity pattern based on the function and the state similarity data of the second state similarity pattern.

Furthermore, the second state similarity pattern is first obtained state similarity pattern among the plurality of state similarity patterns.

Furthermore, the chamber monitoring apparatus obtaining a reference state data comprises: transmitting radio waves in the specific frequency range into the inside of the chamber N times and receiving reflected radio waves in the inside of the chamber N times, wherein N is natural number in the IDLE duration of the chamber or in the duration corresponding to one of the plurality of processes, generating a plurality of fourth state data by measuring the state of the chamber N times based on the received radio waves N times; and obtaining the reference state data based on the plurality of fourth state data.

A chamber monitoring apparatus of monitoring a state of the chamber according to an embodiment of the present disclosure, wherein a process cycle including a plurality of processes is performed one or more times in the chamber, comprises: an antenna configured to transmit radio waves in a specific frequency range into an inside of the chamber and receive reflected radio waves from the inside of the chamber; a bracket configured to fix the antenna to an outside of the chamber; a signal processor configured to apply an electrical signal to the antenna and obtain an electrical signal from the antenna; and a controller configured to control the signal processor and generate a state data of the chamber based on the obtained electrical signal,
wherein the controller is configured to: obtain a reference state data for monitoring the state of the chamber, wherein the reference state data is a first reference state data of the chamber measured in IDLE duration of the chamber or a second reference state data of the chamber measured in a duration corresponding to one of the plurality of processes, control the signal processor, such that the antenna transmits radio waves M times and receive radio waves M times, to obtain electrical signals according to the received radio waves, wherein M is natural number and is equal or larger than 2, generate a plurality of third state data by measuring the state of the chamber based on the electrical signals, calculate similarities between each of the plurality of third state data and the reference state data and obtain a plurality of pieces of state similarity data using the similarities, obtain a plurality of state similarity patterns configured in unit of the process cycle by matching a process duration data for durations in which each of the plurality of processes is performed and the plurality of pieces of state similarity data, and determine whether the chamber is performed in a normal operation or predicting when the chamber will be entered in an abnormal operation using two or more state similarity patterns among the plurality of state similarity patterns.

Furthermore, the controller is configured to: select two or more state similarity data among the plurality of pieces of state similarity data, wherein a state similarity data corresponding to a first process is selected in each of the plurality of state similarity patterns, determine a function for predicting the abnormal operation based on the two or more state similarity data, wherein the function is determined based on a time variable, and predict, as a time of the abnormal operation of the chamber, a first time that a result value of the function calculated according to the time variable is equal to or smaller than a preconfigured similarity threshold.

Furthermore, the controller is configured to: repeatedly predict when the chamber will be entered in the abnormal operation at each time when the state similarity pattern is additionally obtained.

Furthermore, the controller is configured to: select a first state similarity pattern lastly obtained among the plurality of state similarity patterns, select a second state similarity pattern, different the first state similarity pattern, among the plurality of state similarity patterns, calculate difference values between the first state similarity pattern and the second state similarity pattern according to each process and a corresponding time in the each process, and determine that the chamber is operated in abnormal in a process corresponding to a difference value exceeding a preconfigured similarity threshold among the difference values.

Furthermore, the controller is configured to: determine the preconfigured similarity threshold according to an interval between the first state similarity pattern and the second state similarity pattern within the plurality of state similarity patterns.

Furthermore, the controller is configured to: adjust state similarity data of the first state similarity pattern based on state similarity data of the second state similarity pattern, and calculate difference values between the adjusted state similarity data of the first state similarity pattern and the state similarity data of the second state similarity pattern.

Furthermore, the controller is configured to: select two or more state similarity data among the plurality of pieces of state similarity data, wherein a state similarity data corresponding to a first process is selected in each of the plurality of state similarity patterns, determine a function for predicting the abnormal operation based on the two or more state similarity data, wherein the function is determined based on a time variable, and adjust the state similarity data of the first state similarity pattern based on the function and the state similarity data of the second state similarity pattern.

Furthermore, the second state similarity pattern is first obtained state similarity pattern among the plurality of state similarity patterns.

Furthermore, the controller is configured to: transmit radio waves in a specific frequency range into the inside of the chamber N times and receiving reflected radio waves in the inside of the chamber N times, wherein M is natural number in the IDLE duration of the chamber or in the duration corresponding to one of the plurality of processes, generate a plurality of fourth state data by measuring the state of the chamber N times based on the received radio waves N times, and obtain the reference state data based on the plurality of fourth state data.

A method of determining error correction function for correcting measurement error between parameter sets caused by an installation and removal of a chamber monitoring apparatus using P chamber monitoring apparatuses, wherein P is natural number and is equal to or greater than 1 and the parameter sets is one among (i) S-parameter set, (ii) H-parameter set, (iii) Y-parameter set, (iv) Z-parameter set and (v) parameter set induced from one of S-parameter set, H-parameter set, Y-parameter set and Z-parameter set, according to an embodiment of the present disclosure, the method comprises: generating a reference parameter set of a chamber by transmitting radio waves in a specific frequency range to an inside of the chamber after installing a first chamber monitoring apparatus, among the P chamber monitoring apparatuses, within a first region of outside of the chamber in a first process state; generating L first parameter sets by repeatedly performing a first operation N times for each of the P chamber monitoring apparatuses, wherein N is equal to or greater than 2 and L is P multiplied by N; determining a first learning model including a plurality of first error correction parameters; updating the plurality of first error correction parameters to a plurality of second error correction parameters by repeatedly performing a second operation until difference information between the reference parameter set and an output parameter set is included in a predetermined range, wherein the output parameter set is obtained by inputting one of the L first parameter sets to the first learning model; and determining a second learning model including the plurality of second error correction parameters as the error correction function,
wherein the second operation comprises: obtaining a first output parameter set by inputting a first parameter set of the L first parameter sets to the first learning model, wherein the first parameter set is not input to the first learning model previously, and obtaining a first difference information between the reference parameter set and the first output parameter set and modifying the plurality of first error correction parameters based on the first difference information,
wherein the first operation comprises: removing a chamber monitoring apparatus from the chamber, re-installing the chamber monitoring apparatus within the first region and transmitting radio waves in the specific frequency range to the inside of the chamber, wherein the chamber is in the first process state, and receiving radio waves reflected from the inside of the chamber and generating a first parameter set based on the received radio waves.

Furthermore, the first process state is an IDLE state of the chamber.

Furthermore, the first process state is a state in which one of a plurality of processes that may be performed in the chamber is executed.

Furthermore, the first region corresponds to a viewport formed on the chamber.

Furthermore, the chamber monitoring apparatus generating the reference parameter set comprises: transmitting the radio waves M times without removal of the chamber monitoring apparatus in the first region, wherein M is natural number and is equal to or greater than 1; receiving radio waves reflected from the inside of the chamber M times and obtaining M second parameter sets based on each of the received radio waves M times; and generating the reference parameter set of the chamber using the M second parameter sets.

Furthermore, the first learning model is based on a single layer perceptron.

Furthermore, the first learning model is based on a multi-layer perceptron.

A method of determining error correction function for correcting measurement error between parameter sets corresponding to each of a plurality of chambers using P chamber monitoring apparatuses, wherein P is natural number and is equal to or greater than 1 and the parameter sets is one among (i) S-parameter set, (ii) H-parameter set, (iii) Y-parameter set, (iv) Z-parameter set and (v) parameter set induced from one of S-parameter set, H-parameter set, Y-parameter set and Z-parameter set, according to an embodiment of the present disclosure, the method comprises: generating a reference parameter set of a first chamber by transmitting radio waves in a specific frequency range to an inside of the first chamber after installing a first chamber monitoring apparatus, among the P chamber monitoring apparatuses, within a first region of outside of the chamber in a first process state; generating L first parameter sets by repeatedly performing a first operation N times for each of the P chamber monitoring apparatuses, wherein N is equal to or greater than 2 and L is P multiplied by N; determining a first learning model including a plurality of first error correction parameters; updating the plurality of first error correction parameters to a plurality of second error correction parameters by repeatedly performing a second operation until difference information between the reference parameter set and an output parameter set is included in a predetermined range, wherein the output parameter set is obtained by inputting one of the L first parameter sets to the first learning model; and determining a second learning model including the plurality of second error correction parameters as the error correction function,
wherein the second operation comprises: obtaining a first output parameter set by inputting a first parameter set of the L first parameter sets to the first learning model, wherein the first parameter set is not input to the first learning model previously; and obtaining a first difference information between the reference parameter set and the first output parameter set and modifying the plurality of first error correction parameters based on the first difference information,
wherein the first operation comprises: installing a chamber monitoring apparatus to a first regions of a second chamber selected among the plurality of the chambers and transmitting radio waves in the specific frequency range to the inside of the second chamber, wherein the second chamber is in the first process state and the second chamber is not selected previously among the plurality of the chambers; receiving radio waves reflected from the inside of the chamber and generating a first parameter set based on the received radio waves.

Furthermore, the first process state is an IDLE state.

Furthermore, the first process state is a state in which one of a plurality of processes that may be performed in the chamber is executed.

Furthermore, the first region corresponds to a viewport of each of the plurality of the chambers.

Furthermore, the chamber monitoring apparatus generating the reference parameter set comprises: transmitting the radio waves M times to the inside of the first chamber without removal of the first chamber monitoring apparatus from the first chamber, wherein M is natural number and is equal to or greater than 1; receiving radio waves reflected from the inside of the first chamber M times and obtaining M second parameter sets based on each of the received radio waves M times; and generating the reference parameter set of the first chamber using the M second parameter sets.

Furthermore, the first learning model is based on a single layer perceptron.

Furthermore, the first learning model is based on a multi-layer perceptron.

Furthermore, the first chamber is included in the plurality of the chambers.

Furthermore, the first chamber is not included in the plurality of the chambers.

A method of determining error correction function for correcting measurement error between parameter sets caused by an installation and removal of a chamber monitoring apparatus and measurement error between parameter sets corresponding to each of Q chambers using P chamber monitoring apparatuses, wherein P is natural number and is equal to or greater than 1, Q is natural number is equal to or greater than 2, and the parameter sets is one among (i) S-parameter set, (ii) H-parameter set, (iii) Y-parameter set, (iv) Z-parameter set and (v) parameter set induced from one of S-parameter set, H-parameter set, Y-parameter set and Z-parameter set, according to an embodiment of the present disclosure, the method comprises: generating a reference parameter set of a first chamber by transmitting radio waves in a specific frequency range to an inside of the first chamber after installing a first chamber monitoring apparatus, among the P chamber monitoring apparatuses, within a first region of outside of the chamber in a first process state; generating L first parameter sets by repeatedly performing a first operation Q times for each of the P chamber monitoring apparatuses, wherein Q is equal to or greater than 2, the first operation is that a third operation is repeatedly performed N times for each of the Q chambers and L is a product of P, Q and N; determining a first learning model including a plurality of first error correction parameters; updating the plurality of first error correction parameters to a plurality of second error correction parameters by repeatedly performing a second operation until difference information between the reference parameter set and an output parameter set is included in a predetermined range, wherein the output parameter set is obtained by inputting one of the L first parameter sets to the first learning model; and determining a second learning model including the plurality of second error correction parameters as the error correction function, wherein the second operation comprises: obtaining a first output parameter set by inputting a first parameter set of the L first parameter sets to the first learning model, wherein the first parameter set is not input to the first learning model previously; and obtaining a first difference information between the reference parameter set and the first output parameter set and modifying the plurality of first error correction parameters based on the first difference information, wherein the third operation comprises: removing a chamber monitoring apparatus from the chamber and re-installing the chamber monitoring apparatus in the first region and transmitting radio waves in the specific frequency range to the inside of the chamber, wherein the chamber is in the first process state; receiving radio waves reflected from the inside of the chamber and generating a first parameter set based on the received radio waves.

A method of monitoring a first chamber using a parameter set by a chamber monitoring apparatus, wherein the parameter set is one among (i) S-parameter set, (ii) H-parameter set, (iii) Y-parameter set, (iv) Z-parameter set and (v) parameter set induced from one of S-parameter set, H-parameter set, Y-parameter set and Z-parameter set, according to an embodiment of the present disclosure, the method comprises: obtaining a reference parameter set for monitoring the first chamber; installing the chamber monitoring apparatus within a first region of outside of the first chamber; transmitting radio waves in a specific frequency range to an inside of the first chamber, wherein the first chamber is in one of (i) an IDLE state and (ii) a plurality of processes that may be performed in the chamber; receiving radio waves reflected from the inside of the chamber and generating a first parameter set based on the received radio waves; obtaining a second parameter set adjusted from the first parameter set by inputting the first parameter set to an error correction function; calculating similarities for each of second parameters included in the second parameter set by comparing the reference parameter set and the second parameter set; and obtaining monitoring information of the first chamber based on the similarities for each of second parameters,
wherein the error correction function is generated by: generating a plurality of second parameter sets for at least one chamber by measuring each of the at least one chamber by repeatedly installing and removing at least one chamber monitoring apparatus at least once; and modifying error correction parameters included in the error correction function using each of the plurality of second parameter sets sequentially until an output parameter set satisfies a predetermined condition, wherein the output parameter set is output by inputting one of the plurality of second parameter sets to the error correction function.

Furthermore, the first chamber is included in the at least one chamber.

Furthermore, the first chamber is not included in the at least one chamber.

Furthermore, the monitoring information is for determining whether the chamber is performed in a normal operation or predicting when the chamber will be entered in an abnormal operation.

Furthermore, the predetermined condition is that difference information between the reference parameter set and the output parameter set is included in a predetermined range.

A method of monitoring a state of a chamber by a chamber monitoring apparatus, according to an embodiment of the present disclosure, the method comprises: obtaining process duration data for identifying a process duration of each of a plurality of processes which is performed in the chamber, wherein the plurality of processes include a first process and a second process different from the first process; confirming a process currently being performed in the chamber based on the process duration data; obtaining, from a memory, a first reference state data corresponding to the first process based on the confirmed process being the first process, wherein the first reference state data is pre-measured state data of the chamber in the first process; transmitting radio waves of a specific frequency range and receiving reflected radio waves from an inside of the chamber during a first process duration in which the first process is performed; obtaining a first state data by measuring a state of the chamber based on the received radio waves within the first process duration; calculating a first similarity using the first reference state data and the first state data; determining whether the chamber is performed in a normal operation in the first process based on the first similarity; confirming a second process which is newly started in response to determine the first process being ended and a new process being started based on the process duration data; obtaining, from the memory, a second reference state data corresponding to the second process, wherein the second reference state data is pre-measured state data of the chamber in the second process; transmitting radio waves of the specific frequency range and receiving reflected radio waves from the inside of the chamber during a second process duration in which the second process is performed; obtaining a second state data by measuring a state of the chamber based on the received radio waves within the second process duration; calculating a second similarity using the second reference state data, instead of the first reference data, and the second state data; and determining whether the chamber is performed in the normal operation in the second process based on the second similarity.

Furthermore, the chamber monitoring apparatus determining whether the chamber is performed in the normal operation in the first process comprises: determining the chamber being performed in the normal operation based on the first similarity exceeding a preconfigured threshold similarity; and determining the chamber being performed in an abnormal operation based on the first similarity being equal to or smaller than the preconfigured threshold similarity.

Furthermore, the chamber monitoring apparatus determining whether the chamber is performed in the normal operation in the second process comprises: determining the chamber being performed in the normal operation based on the second similarity exceeding a preconfigured threshold similarity; and determining the chamber being performed in an abnormal operation based on the second similarity being equal to or smaller than the preconfigured threshold similarity.

Furthermore, the chamber monitoring apparatus receiving reflected radio waves from the inside of the chamber during the first process duration comprises: transmitting radio waves of the specific frequency range M times and receiving reflected radio waves M times from the inside of the chamber during the first process duration, wherein M is natural number. Furthermore, the chamber monitoring apparatus obtaining the first reference state data comprises: obtaining M first state data by measuring the state of the chamber based on the received radio waves M times within the first process duration.

Furthermore, the chamber monitoring apparatus calculating the first similarity comprises: calculating M first similarities using the first reference state data and each of the M first state data; Furthermore, the chamber monitoring apparatus determining whether the chamber is performed in the normal operation in the first process comprises: determining the chamber being performed in an abnormal operation based on at least one of the M first similarities being equal to or smaller than a preconfigured threshold similarity. Furthermore, the chamber monitoring apparatus receiving reflected radio waves from the inside of the chamber during the second process duration comprises: transmitting radio waves of the specific frequency range M times and receiving reflected radio waves M times from the inside of the chamber during the second process duration, wherein M is natural number; Furthermore, the chamber monitoring apparatus obtaining the second reference state data comprises: obtaining M second state data by measuring the state of the chamber based on the received radio waves M times within the second process duration; Furthermore, the chamber monitoring apparatus calculating the second similarity comprises: calculating M second similarities using the second reference state data and each of the M second state data; Furthermore, the chamber monitoring apparatus determining whether the chamber is performed in the normal operation in the second process comprises: determining the chamber being performed in an abnormal operation based on at least one of the M second similarities being equal to or smaller than a preconfigured threshold similarity.

Furthermore, the method further comprises: transmitting radio waves of the specific frequency range to the inside of the chamber more than Q times and receiving reflected radio waves from the inside of the chamber more than Q times in each of a fourth process duration in which the first process is performed and a fifth process duration in which the second process is performed, wherein Q is natural number, the fourth process duration in which the first process is performed before the first process duration and the fifth process duration in which the second process is performed before the second process duration; obtaining N fourth state data by measuring a state of the chamber based on the received radio waves more than Q times within the fourth process duration and obtaining P fifth state data by measuring a state of the chamber based on the received radio waves more than Q times within the fifth process duration, wherein each of N and P is natural number and N is same or different from P; obtaining the first reference data based on the N fourth state date and obtaining the second reference data based on the P fifth state date; and storing, to the memory, the first reference data and the second reference data.

A chamber monitoring apparatus of monitoring a state of the chamber according to the present disclosure comprises: an antenna configured to transmit radio waves in a specific frequency range into an inside of the chamber and receive reflected radio waves from the inside of the chamber; a signal processor configured to apply an electrical signal to the antenna and obtain an electrical signal from the antenna; a memory configured to store (i) a process duration data for identifying a process duration of each of a plurality of processes which is performed in the chamber and (ii) a reference state data of the chamber, wherein the plurality of processes include a first process and a second process different from the first process; and a controller configured to control the signal processor and generate a state data of the chamber based on the obtained electrical signal, wherein the controller is configured to: confirm a process currently being performed in the chamber based on the process duration data, obtain, from the memory, a first reference state data corresponding to the first process based on the confirmed process being the first process, wherein the first reference state data is pre-measured state data of the chamber in the first process, control the signal processor to transmit the radio waves and receive reflected radio waves from an inside of the chamber during a first process duration in which the first process is performed, obtain a first state data by measuring a state of the chamber based on the received radio waves within the first process duration, calculate a first similarity using the first reference state data and the first state data, determine whether the chamber is performed in a normal operation in the first process based on the first similarity, confirm a second process which is newly started in response to determine the first process being ended and a new process being started based on the process duration data, obtain, from the memory, a second reference state data corresponding to the second process, wherein the second reference state data is pre-measured state data of the chamber in the second process, control the signal processor to transmit the radio waves and receive reflected radio waves from the inside of the chamber during a second process duration in which the second process is performed, obtain a second state data by measuring a state of the chamber based on the received radio waves within the second process duration, calculate a second similarity using the second reference state data, instead of the first reference data, and the second state data, and determine whether the chamber is performed in the normal operation in the second process based on the second similarity.

Furthermore, the controller is configured to: determine the chamber being performed in the normal operation based on the first similarity exceeding a preconfigured threshold similarity, and determine the chamber being performed in an abnormal operation based on the first similarity being equal to or smaller than the preconfigured threshold similarity.

Furthermore, the controller is configured to: determine the chamber being performed in the normal operation based on the second similarity exceeding a preconfigured threshold similarity, and determine the chamber being performed in an abnormal operation based on the second similarity being equal to or smaller than the preconfigured threshold similarity.

Furthermore, the controller is configured to: control the signal processor to transmit the radio waves M times and to receive reflected radio waves M times from the inside of the chamber during the first process duration, wherein M is natural number, obtain M first state data by measuring the state of the chamber based on the received radio waves M times within the first process duration, calculate M first similarities using the first reference state data and each of the M first state data, and determine the chamber being performed in an abnormal operation based on at least one of the M first similarities being equal to or smaller than a preconfigured threshold similarity.

Furthermore, the controller is configured to: control the signal processor to transmit the radio waves M times and receive reflected radio waves M times from the inside of the chamber during the second process duration, wherein M is natural number, obtain M second state data by measuring the state of the chamber based on the received radio waves M times within the second process duration, calculate M second similarities using the second reference state data and each of the M second state data, and determine the chamber being performed in an abnormal operation based on at least one of the M second similarities being equal to or smaller than a preconfigured threshold similarity.

Furthermore, the controller is configured to: control the signal processor to transmit the radio waves to the inside of the chamber more than Q times and receive reflected radio waves from the inside of the chamber more than Q times in each of a fourth process duration in which the first process is performed and a fifth process duration in which the second process is performed, wherein Q is natural number, the fourth process duration in which the first process is performed before the first process duration and the fifth process duration in which the second process is performed before the second process duration, obtain N fourth state data by measuring a state of the chamber based on the received radio waves more than Q times within the fourth process duration and obtain P fifth state data by measuring a state of the chamber based on the received radio waves more than Q times within the fifth process duration, wherein each of N and Pis natural number and N is same or different from P, obtain the first reference data based on the N fourth state date and obtain the second reference data based on the P fifth state date, and store, to the memory, the first reference data and the second reference data.

Meanwhile, in describing embodiments of the present disclosure, terms used may be defined as follows.
Process State: A plurality of processes is performed in a chamber according to a process cycle. In addition, a state in which no process is performed in the chamber may be referred to as idle state. That is, the process state according to an embodiment of the present disclosure may mean that any one of the plurality of processes is being performed in the chamber, or no process is being performed, among the plurality of processes or the idle state. For example, the idle state may mean a state in which no process is performed in the chamber. As another example, the first process state (or the second to Nth process states) may mean a state in which the first process state (or the second to Nth process states) included in the plurality of processes is performed in the chamber.
Idle State: It may be a process state in which no process is performed in the chamber, such as a state in which the assembly of process equipment is completed during equipment manufacturing, or a state in which preventive maintenance of process equipment is completed. In addition, it may mean a state in which no process is performed in the chamber after one process cycle is completed and before the next process cycle is performed. In the present disclosure, the idle state may also be understood as a process state.
Process Cycle: A plurality of processes is performed in the chamber according to the process cycle. Here, the process cycle may include an idle duration in which the chamber is in an idle state before the plurality of processes are performed. In other words, the process cycle in the present disclosure may be a concept that includes both an idle duration and a duration in which the plurality of processes are performed. For example, when the plurality of processes is composed of the first process to the Nth process, the process cycle may mean “an idle duration+a duration in which the first process to the Nth process are performed.”
State data: State data may be a set of parameters reflecting the geometric and electrical state inside the chamber. For example, parameters that may be utilized as state data may be i) S-parameters, ii) H-parameters, and iii) Y-parameters, iv) Z-parameters, v) a combination of at least two parameters selected from S-parameters, H-parameters, Y-parameters, and Z-parameters, vi) parameters derived from S-parameters, H-parameters, Y-parameters, and Z-parameters, or vii) parameters derived from a combination of at least two parameters selected from S-parameters, H-parameters, Y-parameters, and Z-parameters. The monitoring device may measure the frequency characteristics inside the chamber to derive a set of parameters, and may use the set of parameters to determine the state of the chamber (e.g., whether the chamber is in a normal operating state).
Normal/abnormal operation: This is a classification for distinguishing between normal and abnormal operation of the chamber. Here, abnormal operation may mean at least one of failure, aging, replacement, replacement of parts, and occurrence of an abnormality in the chamber. For example, the normal operation of chamber is determined by determining whether the chamber is currently operating normally or whether the chamber is operating abnormally (for example, at least one of failure, aging, replacement, replacement of parts, and occurrence of an abnormality in the chamber).

In addition, predicting a time of the abnormal operation of the chamber may refer to predicting a time when the chamber changes from normal operation to abnormal operation. For example, predicting a time of the abnormal operation refer to predicting a time when chamber replacement, chamber component replacement, or chamber inspection is required.

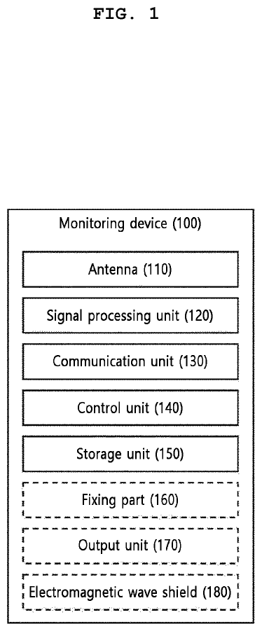

FIG. 1 is a block diagram illustrating a monitoring device according to an embodiment. Referring to FIG. 1, a monitoring device 100 may include an antenna 110, a signal processing unit 120, a communication unit 130, a control unit 140, and a storage unit 150.

The monitoring device 100 may transmit and receive radio waves through the antenna 110. The antenna 110 may receive an electrical signal to transmit radio waves. The antenna 110 may receive radio waves and convert the radio waves into an electrical signal. The monitoring device 100 may include one antenna 110. Alternatively, the monitoring device 100 may include two or more antennas 110. In this case, one or some of the two or more antennas 110 may be for transmitting radio waves and the others may be for receiving radio waves. Alternatively, each of the two or more antennas 110 may be for transmitting and receiving radio waves at different locations.

The monitoring device 100 may apply an electrical signal to the antenna 110 and obtain an electrical signal from the antenna 110 through the signal processing unit 120. The signal processing unit 120 may apply, to the antenna 110, an electrical signal having a specific frequency range. The signal processing unit 120 may control a frequency and an amplitude of a radio wave to be transmitted through the the antenna 110, and may sense information regarding a frequency and an amplitude of a radio wave received through the antenna 110. More specific details of this will be provided later.

The monitoring device 100 may generates state data through the signal processing unit 120. More specific details of this will be provided later.

The monitoring device 100 may perform communication with the outside through the communication unit 130. For example, the communication unit 130 may transmit state data and monitoring information to the outside.

The communication unit 130 may perform wired or wireless communication. The communication unit 130 may be, for example, a wired/wireless local area network (LAN) module, a WAN module, an Ethernet module, a Bluetooth module, a Zigbee module, a universal serial bus (USB) module, an IEEE 1394 module, a Wi-Fi module, an Ether-CAT module, a device net module, or a combination thereof, but is not limited thereto.

The monitoring device 100 may generate monitoring information through the control unit 140. The control unit 140 may generate monitoring information based on state data. More details on this will be described later.

The control unit 140 may be realized as a computer or a similar device according to hardware, software, or a combination thereof. Hardware-wise, the control unit 140 may be one or a plurality of processors. Alternatively, the control unit 140 may be provided as processors that are physically spaced apart from each other and cooperate through communication. The control unit 140 may be, for example, a central processing unit (CPU), a graphics processing unit (GPU), a digital signal processor (DSP), a state machine, a field programmable gate array (FPGA), an application specific integrated circuit (ASIC), a radio-frequency integrated circuit (RFIC), or a combination thereof, but is not limited thereto. Software-wise, the control unit 140 may be provided in the form of a program that drives the control unit 140 that is hardware.

Meanwhile, operations of all embodiments described in the present disclosure may be controlled and executed by the control unit 140. For example, operations including at least one of Embodiments 1 to 5 described in the present disclosure may be executed under the control of the control unit 140. In other words, the control unit 140 may control overall operations of the monitoring device 100.

The monitoring device 100 may store various types of data and programs in the storage unit 150. For example, the storage unit 150 may store state data generated by the signal processing unit 120. As another example, the storage unit 150 may store monitoring information generated by the control unit 140.

The storage unit 150 may be, for example, a non-volatile semiconductor memory, a hard disk, a flash memory, a solid-state drive (SSD), a random-access memory (RAM), a read-only memory (ROM), an electrically erasable programmable read-only memory (EEPROM), other types of tangible non-volatile recording media, or a combination thereof, but is not limited thereto.

The monitoring device 100 may further include a fixing part 160. The fixing part 160 may fix the antenna 110 at a location near the chamber. For example, the fixing part 160 may fix the antenna 110 such that the antenna 110 and the chamber are spaced a predetermined distance apart. The predetermined distance may be, for example, 1 mm, 3 mm, 5 mm, 7 mm, or 1 cm, but is not limited thereto. As another example, the fixing part 160 may fix the antenna 110 such that the antenna 110 and the chamber are in contact with each other. The fixing part 160 may be, for example, a bracket, but is not limited thereto.

The monitoring device 100 may further include an output part 170. For example, the output part 170 may be a display. The monitoring device 100 may display monitoring information through the display. As another example, the output part 170 may be a speaker. The monitoring device 100 may output an alarm through the speaker.

The monitoring device 100 may further include an electromagnetic wave shield 180. The electromagnetic wave shield 180 prevents the antenna 110 from being influenced by external electromagnetic waves, or reduces the effect. For example, the electromagnetic wave shield 180 may be disposed outside the chamber to surround the antenna 110. The electromagnetic wave shield 180 may be provided with various materials capable of shielding electromagnetic waves.

The monitoring device 100 of an integrated type may be provided. For example, the monitoring device 100 may be provided in the form in which the antenna 110, the signal processing unit 120, the communication unit 130, the control unit 140, the storage unit 150, and the fixing part 160 are integrated.

Alternatively, the monitoring device 100 of a separated type may be provided. For example, the monitoring device 100 may be provided in the form in which the antenna 110 and the other elements are separated.

Not all the elements shown in FIG. 1 are essential elements of the monitoring device, and at least one or some of the elements of the monitoring device shown in FIG. 1 may be omitted. In addition, the monitoring device may further include elements not shown in FIG. 1.

The monitoring device may be realized using a network analyzer, such as a vector network analyzer (VNA).

For example, the signal processing unit, the communication unit, the control unit, and the storage unit may be realized using the network analyzer.

As another example, the signal processing unit may be realized using the network analyzer. In this case, in addition to the network analyzer, the monitoring device may include an additional device for realizing the communication unit, the control unit, and the storage unit.

The monitoring device may be installed in the chamber.

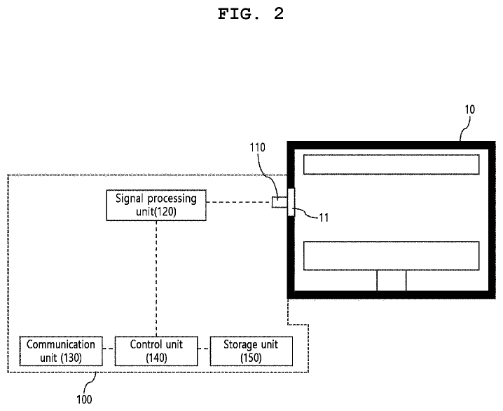

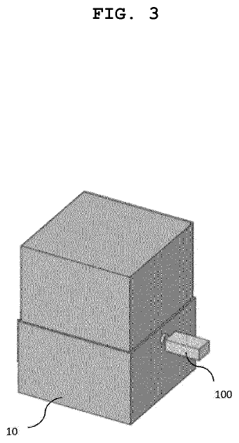

FIGS. 2 and 3 are schematic diagrams illustrating a monitoring device installed at a chamber, according to an embodiment.

Referring to FIG. 2, an antenna may be located outside the chamber 10. For example, the antenna may be located at the outside of a viewport 11 formed in the chamber 10.

The antenna may be installed outside the chamber 10 by a fixing part. For example, the antenna may be installed outside the chamber 10 by the fixing part such that the antenna and the chamber 10 are spaced a predetermined distance apart. As another example, the antenna may be installed outside the chamber 10 by the fixing part such that the antenna and the chamber 10 are in contact with each other.

Although not shown, the antenna may be located inside the chamber. For example, the antenna may be located at the inside of the viewport formed in the chamber. The antenna may be installed inside the chamber by the fixing part. However, when the antenna is located inside the chamber, the antenna may contaminate the chamber or the antenna may be contaminated as a process progresses, which may be disadvantageous compared to locating the antenna outside the chamber.

Referring to FIG. 3, in the case of the monitoring device 100 of the integrated type, the monitoring device 100 may be used in the form of being mounted to the chamber 10.

In the case of the monitoring device of the separated type, the monitoring device may be used in the form in which only one or some elements of the monitoring device are mounted to the chamber and the other elements are connected to the elements mounted to the chamber via wires. For example, the monitoring device may be used in the form in which the antenna is mounted to the chamber and the other elements are connected to the antenna via wires. The wire may be, for example, a coaxial cable. For example, in the case of the monitoring device of the separated type, only some components (for example, an antenna) may be attached to an exterior of the chamber, while the remaining separated from the some components and connected to the some components through wired or wireless communication. That is, in the case of the monitoring device of the separated type, at least some of the components of the monitoring device may be designed to be separable, and the respective components may be designed to be assembled according to a purpose of use.

In this case, the meaning of being assemblable may refer to a configuration in which the some components and the remaining components are assembled so as to be directly connected without a connection wire such as a coaxial cable. Further, as described above, the some components and the remaining components may be connected through a wire or wirelessly. For example, when the some components and the remaining components are wirelessly connected, each of the some components and the remaining components may further include a wireless communication unit for wireless communication.

It has been described with reference to FIGS. 2 and 3 that the antenna is located corresponding to the viewport, but in addition to the viewport, the antenna may be located corresponding to an area, such as a ceramic, of the chamber through which radio waves penetrate. For example, in addition to the existing viewport, an additional port for mounting the antenna is formed in the chamber and the antenna may be located corresponding to to the additional port.

In addition, it has been described with reference to FIGS. 2 and 3 that the monitoring device includes one antenna, but the monitoring device may include two or more antennas as described above. In this case, one or some of the two or more antennas may be mounted to an area of the chamber and the others may be mounted to another area of the chamber.

Hereinafter, a method of monitoring a status of a chamber will be described in more detail. The monitoring device may generate state data.

The state data may be related to radio waves (hereinafter, referred to as “incident waves”) incident from the antenna to inside the chamber, and radio waves (hereinafter, referred to as “reflected waves”) reflected by the internal space of the chamber and received by the antenna. The state data may be related to a voltage applied to the antenna and a voltage output from the antenna.

The state data may correspond to a specific frequency range. The state data may be generated for a specific frequency range.

The state data may be defined using the incident waves and the reflected waves. For example, the state data may be defined using the ratio between the incident waves and the reflected waves, for example, the ratio of the reflected waves to the incident waves. The state data may be, for example, S-parameters, H-parameters, Y-parameters, Z-parameters, or parameters calculated therefrom, but is not limited thereto.

In some embodiments, the state data may be S-parameters.

In some other embodiments, the state data may be H-parameters.

In some other embodiments, the state data may be Y-parameters.

In some other embodiments, the state data may be Z-parameters.

In some other embodiments, the state data may be parameters derived from at least one selected from the group of S-parameters, H-parameters, Y-parameters, and Z-parameters.

In addition, in some other embodiments, the state data may be a combination of at least two parameters selected from the group of S-parameters, H-parameters, Y-parameters, and Z-parameters.

In addition, in some other embodiments, the state data may be parameters derived from a combination of at least two parameters selected from the group of S-parameters, H-parameters, Y-parameters, and Z-parameters.

That is, the state data may be i) S-parameters, ii) H-parameters, iii) Y-parameters, iv) Z-parameters, v) a combination of at least two parameters selected from the group of S-parameters, H-parameters, Y-parameters, and Z-parameters, vi) parameters derived from S-parameters, H-parameters, Y-parameters, and Z-parameters, or vii) parameters derived from a combination of at least two parameters selected from the group of S-parameters, H-parameters, Y-parameters, and Z-parameters.

For example, the state data may be represented as the following n×2 matrix.
(the first frequency) (the size of reflected waves/size of incident waves)
(the second frequency) (the size of reflected waves/size of incident waves)
. . .
(the n-th frequency) (the size of reflected waves/size of incident waves)

For another example, the state data may be represented as the following n×3 matrix.
(the first frequency) (the size of incident waves) (the size of reflected waves)
(the second frequency) (the size of incident waves) (the size of reflected waves).
. . .
(the n-th frequency) (the size of incident waves) (the size of reflected waves)

Here, n is the number of frequencies at which state data is measured, the first frequency is a lower limit of the frequency at which state data is measured, the nth frequency is an upper limit of the frequency at which state data is measured, and the first to nth frequencies are a frequency range at which state data is measured.

Meanwhile, when the monitoring device 100 measures state data, the state data may be measured by transmitting radio waves corresponding to each of the first frequency to the nth frequency at least once. For example, parameters are measured while transmitting the first frequency wave m times, parameters are measured while transmitting the second frequency waves m times, and so on until parameters measured while transmitting the nth frequency wave m times. Herein, the strength of radio waves of the first frequency to the nth frequency during m transmissions may be different or the same for each transmission.

As another example, parameters are measured while transmitting once from the first frequency to the nth frequency, parameters are measured while transmitting once more from the first frequency to the nth frequency, and so on until parameters are measured while transmitting m times from the first frequency to the nth frequency. Herein, the strength of radio waves of each transmitted frequency may be different or the same for each transmission.

Here, n may be determined according to resolution of the frequency to be measured, i.e., the interval between frequencies. For example, upon measuring state data between 3 GHz and 8.5 GHz, when n is 55, the frequency characteristics may be measured in units of 0.1 GHz. As another example, when n is 11, the frequency characteristics may be measured in units of 0.5 GHz.

The state data may include parameter values for a specific frequency range. In the above example, (the size of reflected waves/size of incident waves), (the size of incident waves), and (the size of reflected waves) may be parameter values. The number of parameter values included in the state data may be, for example, at least 500, 1000, 1500, or 2000, but is not limited thereto. Regarding the state data, a plurality of pieces of state data belonging to a specific frequency range may include a plurality of peaks belonging to the specific frequency range. The number of peaks included in the state data may be, for example, at least 5, 10, 20, 50, or 100, but is not limited thereto.

The state data may correspond to a specific time point. The state data may be generated at a specific time point. For example, the specific time point may be a time point at which a process is not in progress, for example, a time point at which assembly of process equipment is completed when the equipment is manufactured, or a time point at which preventive maintenance of process equipment is completed. As another example, the specific time point may be a time point at which a process is in progress, for example, a time point at a specific process step.

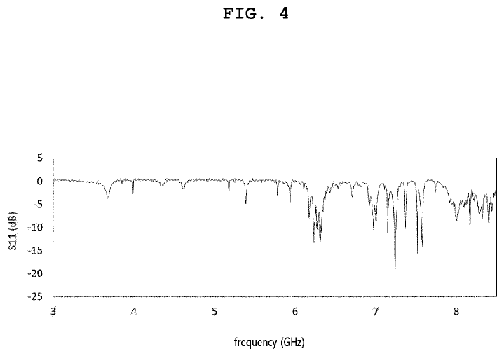

FIG. 4 is a graph illustrating S11 parameter, an example of state data. FIG. 4 shows the S11 parameter in dB for the frequency range of 3 GHz to 8.5 GHZ. In FIG. 4, it is found that there are several tens of peaks, but the number of peaks may vary depending on the criterion for counting peaks. For example, in FIG. 4, a peak is used to distinguish the characteristics of state data or to distinguish the pattern of state data, in which the criterion may vary depending on its purpose. For example, a peak may be defined as values at which the radio intensity in dB units in each frequency range is greater than or equal to a certain level, and may mean a frequency at which the radio strength of a previous frequency range increases or decreases by a certain amount or more than the radio strength of a current frequency range. In addition, a peak may mean a frequency at which the radio intensity of a previous frequency range increases or decreases by a certain amount or more than the degree of change (i.e., the slope of the graph) of the radio strength of a current frequency range.

State data may reflect a geometric state of the chamber. For example, when the geometric state of a part changes, such as the position or shape of a part included in the chamber, state data after the change may be different from the state data before the change. As another example, the state data in the case that some parts are damaged may be different from the state data in the case that they are not damaged. As another example, the state data in the case that foreign substances exist may be different from the state data in the case that no foreign substances exist inside the chamber.

State data may also reflect the electrical status of the chamber. For example, since conductivity, permittivity, etc. change depending on the material properties of the chamber or part, state data may reflect the electrical status of the chamber. As another example, when a polymer film, etc. is formed on an inner wall of the chamber as the process progresses, since permittivity of the wall changes, the state data may reflect the electrical status of the chamber.

That is, the state data may change depending on the process state within the chamber while a process cycle is repeated. For example, even when the state data measured in the first process state of the process cycle and the state data measured in the second process state do not change in the position or shape of the part included within the chamber, the electrical state within the chamber may change as the process state changes.

According to an embodiment, the monitoring device may transmit radio waves into the inside of the chamber per frequency within a specific frequency range and receive reflected radio waves from the inside of the chamber to generate state data. For example, the monitoring device may transmit radio waves of a first frequency into the inside of the chamber and receive reflected radio waves from the inside of the chamber to generate a first parameter value, and transmit radio waves of a second frequency into the inside of the chamber and receive reflected radio waves from the inside of the chamber to generate a second parameter value. By performing such a procedure for the entire frequency range, the monitoring device may generate state data corresponding to a specific frequency range.

### Embodiment 1: Method of Obtaining Reference State Data

In order to monitor a chamber, a chamber in a process state (e.g., an idle state) that serves as a reference for chamber monitoring may exist, and the chamber in the process state that serves as the reference may be compared with a chamber of the current process state to monitor the chamber with the current process state. In this way, the process state of the chamber that serves as the reference for chamber monitoring may be referred to as a reference state. For example, the reference state may be a golden chamber state. As another example, the reference state may be a process state of a chamber that a user is interested in. The chamber of interest to the user may be, for example, a chamber with a good assembly state, a chamber that has completed preventive maintenance, a chamber with good process results, a chamber in a bad state, a chamber that requires preventive maintenance, or a chamber in an accident state.

In addition, the reference state may be a state in which the chamber process is not performed, such as a state in which the assembly of the process equipment is completed during equipment manufacturing, or a state in which the preventive maintenance of the process equipment is completed. Hereinafter, the process state in which the chamber process is not performed as described above is referred to as an idle state. Herein, the idle state may also mean a process state in which no process is in progress in the chamber after one process cycle is completed and before the next process cycle is performed.

Meanwhile, the reference state may be a process state other than the idle state. For example, when P processes are included in a process cycle, the reference state may be any one of the P processes. In other words, in order to generate reference state data according to an embodiment of the present disclosure, reference state data may be generated in any one of the P processes. In addition, the reference state data may be generated for each of the P processes. For example, the first reference state data for the chamber internal state in the first process to the Pth reference state data for the chamber internal state in the Pth process may be generated.

The monitoring device may generate the state data of the chamber in the reference state (hereinafter referred to as “reference state data”).

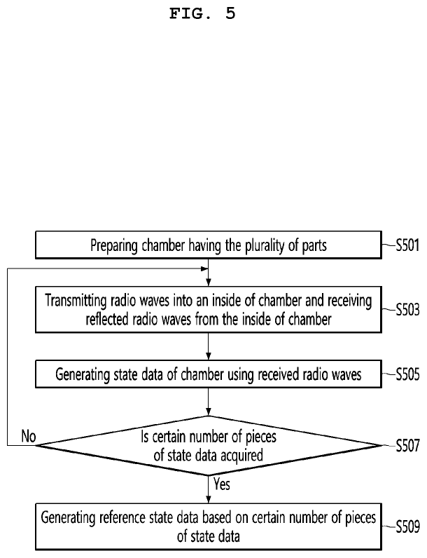

FIG. 5 is a flowchart illustrating a method of generating reference state data according to an embodiment.

Referring to FIG. 5, a method of generating reference state data may include a step of preparing a chamber having a plurality of parts (S501), a step of transmitting radio waves into the inside of the chamber and receiving reflected radio waves from the inside of the chamber (S503), a step of generating state data of the chamber using the received radio waves (S505), a step of determining whether a certain number of pieces of state data is acquired (S507), a step of generating reference state data based on the certain number of pieces of state data (S509).

In step S501, the monitoring device may be installed in the chamber having a plurality of parts. Here, the process state of the chamber may be in the aforementioned reference state. For example, the process state of the chamber may be any one of P processes.

In step S503, the monitoring device may transmit a radio wave of a specific frequency range into the inside of the chamber in the reference state and receive reflected radio waves from the inside of the chamber.

The specific frequency range may be determined in consideration of the characteristics of the monitoring target in the apparatus and method for monitoring the process state of the chamber according to the present disclosure.

For example, as described above, the apparatus and method for monitoring process state of the chamber disclosed herein may monitor whether equipment is properly assembled before the process starts, or whether there are any abnormalities on the inner wall of the equipment or the surfaces of various parts disposed inside the equipment during the process and after the process is completed. That is, the objects to be monitored by the apparatus and method disclosed herein may include the geometrical shape of each of the parts inside the chamber, a level of wear-out of each of the parts, the relative positional relationship between the parts, unnecessary deposition of by-products generated by the process of the target substrate through the chamber on the inner wall of the chamber and the surface of each part inside the chamber, etc. Accordingly, a range of the specific frequency used in the apparatus and method disclosed by the present disclosure may be determined as a frequency band that is advantageous for monitoring the geometrical shape of each part inside the chamber, the relative position between each part, the degree of wear of each part, or unnecessary deposition of by-products generated by the process on the inner wall of the chamber and the surface of each part inside the chamber. Meanwhile, the range of the specific frequency may be determined as a frequency band that is not affected or is relatively less affected by the state of material and energy supplied inside the chamber (e.g., reactive species, etching gas, inert gas flowing into the chamber to perform the necessary process, RF power or their plasma, etc.) while the process for the substrate is being performed in the chamber to be monitored. In other words, the range of the specific frequency may be determined as a frequency band that is relatively unaffected by the state of the material and energy supplied inside the chamber while the process is being performed inside the chamber, to relatively completely measure the process state inside the chamber.

As another example, the specific frequency range may be determined as a frequency band that is affected by the state of the supplied material and energy, to measure the state of the supplied material and energy. For example, when monitoring the electrical/physical characteristics inside a chamber by measuring the frequency characteristics, the state of the supplied material and energy inside the chamber must be measured, and a frequency range in which the characteristics change according to the electrical/physical characteristics must be selected. That is, the specific frequency range may be determined as a frequency band that is affected by the state of the supplied material and energy.

According to some embodiments, the specific frequency range may be determined as a frequency band having a wavelength of 1 mm to 1000 mm. That is, the specific frequency range may be 300 MHz to 300 GHz.

According to some embodiments, the specific frequency range may be determined as a frequency band having a wavelength of 10 mm to 500 mm. That is, the specific frequency range may be 600 MHz to 30 GHz.

According to some embodiments, the specific frequency range may be 1 GHz to 20 GHz.

A specific frequency range may depend on the size of the chamber inside space and/or the size of the parts contained in the chamber.

A lower limit of a specific frequency range may depend on the size of the chamber inside space. For example, the larger the inner space of the chamber, the smaller the lower limit may be.

An upper limit of a specific frequency range may depend on the size of the part included in the chamber. For example, the smaller the size of the part, the larger the upper limit may be.

In step S505, the monitoring device 100 may generate the state data of the chamber in a reference state using the received radio waves. Meanwhile, in step S507, it may be determined whether a predetermined number of pieces of state data has been acquired. When the predetermined number of pieces of state data has not been acquired, the monitoring device may repeat steps S503 to S505 until the predetermined number of pieces of state data is acquired.

Herein, the predetermined number may be a natural number greater than or equal to 1. When the predetermined number is 1, the monitoring device 100 may determine the state data of the chamber generated by one measurement as reference state data. When the predetermined number is two or more, the predetermined number of pieces of state data may be repeatedly acquired, and the reference state data may be generated based on the predetermined number of pieces of state data (S509). For example, an average value, a deviation value, a standard deviation value, a mode value or a median value, etc. of the predetermined number of pieces of state data may be calculated as reference state data. Meanwhile, when the state data is a set of measurement parameters for each frequency, such as the S11 parameter, the monitoring device 100 may calculate the average value, deviation value, standard deviation value, mode, or median value of each measurement parameter, and may configure the set of calculated measurement parameters as reference state data.

Meanwhile, when measuring the predetermined number of pieces of state data, the reference state of the chamber must be the same. For example, in a case that the chamber is in an idle state, when the monitoring device 100 first measures the state data of the chamber, the chamber must remain in the idle state until the predetermined number of pieces of state data are all measured. For example, in the case of a process state in which the chamber is performing a specific process, when the monitoring device 100 first measures the state data of the chamber, the chamber must remain in the corresponding process state until the predetermined number of pieces of state data are all measured.

Meanwhile, if only the reference state is the same upon measuring the predetermined number of pieces of state data, the chamber to be measured may be replaced for each measurement. However, in general, the monitoring device 100 will measure the predetermined number of pieces of state data in the same reference state for one chamber, to generate reference state data.

In addition, the above-described steps S501 to S509 may be performed for each process. For example, if P processes are performed in the chamber, the steps S501 to S509 may be performed for each of the P processes, so that the reference state data for each of the P processes may be generated. In other words, the reference state data may be generated for each process in order to monitor the process state of the chamber and whether there is an abnormality in each process.

### Embodiment 2: Method of Calculating Similarity Between Reference State Data and State Data

Monitoring information may include information on the similarity between the reference state data and the state data measured by the monitoring device 100. The higher the similarity, the more the current process state may be understood or determined to be similar to the reference state. Alternatively, when the similarity exceeds the similarity criterion, the current process state may be understood or determined to be the reference state. In other words, the current process state of the chamber may be determined by referring to the similarity.

The monitoring information may include a scatter plot of state data against reference state data. The scatter plot allows a user to visually check the relationship between the reference state data and the state data. For example, the scatter plot may be a representation of the similarity, as points on a grid, between the reference state data and the measured state data measured according to a predetermined period or a measurement trigger signal indicated by the monitoring device 100. In other words, the scatter plot may be a representation of the similarity, as points on a graph plane, between the reference state data and the state data according to a predetermined period or a measurement trigger signal indicated by the monitoring device 100.

The monitoring information may include a history of the chamber being determined to be in a reference state in the past. The history may include, but is not limited to, the date, time, and number of times when the reference state occurs.

The monitoring information may include a description of the reference state. The description may include, but is not limited to, a description of what process state the reference state means, and may include various contents related to the reference state.

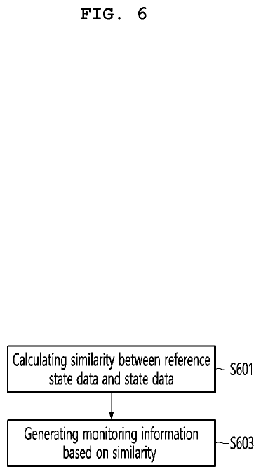

Referring to FIG. 6, it may include a step of calculating the similarity between the state data and the reference state data (S601), and a step of generating the monitoring information based on the similarity (S603). Here, the state data may be a parameter set measured to determine the process state of the corresponding chamber at a time point when the monitoring device 100 measures the chamber. In step S603, the monitoring device 100 may generate monitoring information based on the similarity. For example, according to Embodiment 3, the monitoring device 100 may determine state similarity data based on the calculated similarity. For example, the monitoring device 100 may compare each of the state data measured by each of the plurality of measurement trigger signals indicated to the monitoring device 100 at predetermined intervals with the reference data to calculate a plurality of similarities, generate a plurality of pieces of state similarity data based on the plurality of similarities, and generate monitoring information based on the plurality of pieces of state similarity data.

In step (S601), the monitoring device 100 may calculate the similarity between the state data and the reference state data.

The similarity may be calculated, for example, through a graph similarity algorithm such as an average, a sum of squares (SOS), cosine similarity, correlation integral technique, or convolution technique, but is not limited thereto.

Below, some examples of calculating similarity are described.

As an example of calculating similarity, the monitoring device 100 may calculate similarity by using a difference between the reference state data and the state data within a specific frequency range. For example, referring to Equation 1 below, the monitoring device 100 may calculate the similarity using a sum of squares of differences between the parameter values of the reference state data and the parameter values of the state data within the specific frequency range.

$$Similarity = {{\sum }^{N}}_{n = 1} {( S 11 ( reference state , n ) - S 11 ( process state , n ) )}^{3} \qquad [ Equation 1 ]$$

Here, S11 (reference state) is parameter value of the reference state data, S11 (process state) is parameter value of the state data measured by the monitoring device 100, and N is a total number of data points.

As another example of calculating the similarity, referring to Equation 2, the monitoring device 100 may calculate the similarity by using the cosine similarity between the reference state data and the state data within a specific frequency range.

$$Similarity = \frac{\vec{S 11 ( reference state )} \cdot \vec{S 11 ( process state )}}{‖ \vec{S 11 ( reference state )} ‖ ‖ \vec{S 11 ( process state )} ‖} \qquad [ Equation 2 ]$$

Here, S11 (reference state) represents parameter values of the reference state data in a vector form, and S11 (process state) represents parameter values of the state data in a vector form.

Meanwhile, when expressing Equation 2 in a form of similarity %, it is shown in Equation 3 below. In addition, Equation 3 expresses Equation 2 of a vector form in the form of a scalar.

$$\begin{matrix}Similarity = \frac{\vec{S 11 ( reference state )} \cdot \vec{S 11 ( process state )}}{‖ \vec{S 11 ( reference state )} ‖ ‖ \vec{S 11 ( process state )} ‖} * 100 \% \\ = \frac{\sum S 11 {( reference state )}_{i} \cdot S 11 {( process state )}_{i}}{\sqrt{\sum S 11 {( reference state )}_{i}^{2}} \sqrt{\sum S 11 {( process state )}_{i}^{2}}} * 100 \%\end{matrix} \qquad [ Equation 3 ]$$

### Embodiment 3: Method of Determining and Predicting Process State of the Chamber Using Similarity Pattern

### 1. Problems of Prior Art

As described above, the process state of the target chamber may be determined based on the similarity calculated by comparing the reference state data with the state data measured by the monitoring device 100. However, in a state that the process cycle is performed repeatedly multiple times within the target chamber, even when the chamber performs the same process in normal operation, a phenomenon in which the similarity gradually decreases is found.

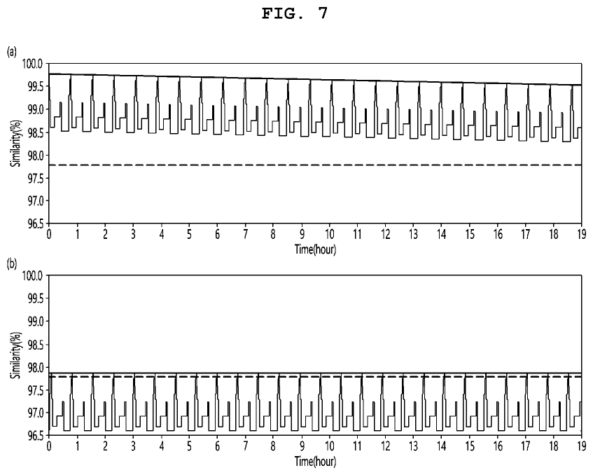

FIG. 7 shows that the similarity gradually decreases as the process cycle is repeated several times, in which an X-axis of the graph shown in FIG. 7 represents time, and a Y-axis represents the similarity between the reference state data and the measured state data.

In addition, FIG. 7(a) shows the state similarity data on the first day of measurement, and FIG. 7(b) shows the state similarity data on the 160th day of measurement. The solid lines in FIG. 7(a) and FIG. 7(b) are to connect the similarities in the same process, which is intended to show the change of the similarity over time.

Referring to FIG. 7(a), it may be seen that the similarity decreases relatively quickly over time on the first day, even though less than a day has passed, and referring to FIG. 7(b), it may be seen that the similarity decreases on the sixteenth day. In addition, it may be seen the state similarity data on the first day have a relatively higher similarity than the dotted line located between 98% and 97.5% similarity, and differs relatively greatly from the dotted line. Meanwhile, it may be seen that the state similarity data on the sixteen day has a similarity that is almost close to the dotted line located between 98% and 97.5% similarity, and appears lower than the dotted line.

As may be seen from FIGS. 7(a) and (b), the similarity between the reference state data and the state data varies over time even in the same process. Therefore, it may be difficult to accurately determine what process is being performed in the chamber or what the current process state of the chamber is, based on only this similarity measurement. That is, when there is a “difference” in the similarities between the state data measured at each of two points and the reference state data, it is not possible to distinguish whether this “difference” is incurred by the difference between the process state of the chamber when the reference state data is measured and the process state of the chamber when the measured state data is measured, or incurred by a change (or deterioration) in the geometrical/electrical characteristics of the chamber.

In addition, a significant difference in the similarity between the state data and the reference state data in each process may mean that the chamber is not performing its function properly. In other words, a decrease in the similarity between the state data and the reference state data over time may mean that the chamber is aging over time, not that a component or specific part of the target chamber is broken. However, as time passes, the chamber ages so that it is not performing its function properly, which leads to make efficient preventive maintenance (PM) difficult. Therefore, a method is needed to predict the point in time when the chamber is not performing its function properly so that PM may be performed efficiently.

Therefore, in Embodiment 3 according to the present disclosure, the monitoring device 100 may obtain state similarity patterns in which the similarity between the state data and the reference state data changes over time. In Embodiment 3, it will be described with respect to a method in which the monitoring device 100 uses these state similarity patterns to determine whether the chamber is currently operating normally and to predict the time point of abnormal operation.

Herein, the state similarity pattern may mean the tendency of similarity change that appears in a plurality of process states included in the process cycle. For example, the state similarity pattern is generated per a process cycle, and the state similarity pattern may include state similarity data for each of the plurality of processes.

For example, the monitoring device 100 may calculate similarities between the reference state data and state data measured at a predetermined period or by each of a plurality of measurement trigger signals indicated to the monitoring device 100 and obtain a plurality of pieces of state similarity data using the calculated similarities. In addition, the monitoring device 100 may obtain the state similarity patterns using the state similarity data according to the method described below.

In other words, the state similarity pattern may be understood as a set of a plurality of pieces of state similarity data generated based on the similarities between the reference state data and the chamber state data during one process cycle.

### 2. Embodiment 3-1: Method of Obtaining State Similarity Pattern

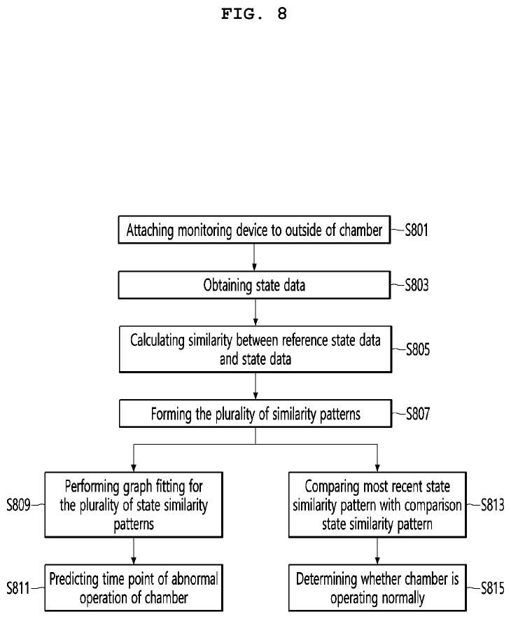

FIG. 8 schematically illustrates a method of determining whether a chamber is operating normally or predicting a time point of an abnormal operation of a chamber according to Embodiment 3. Referring to FIG. 8, a monitoring device 100 may be attached to the outside of the chamber (S801). For example, the monitoring device 100 may be attached to a viewport 11 of the chamber 10.

The monitoring device 100 may transmit radio waves having a specific frequency range into the inside of the chamber 10, and obtain state data of the chamber 10 based on radio waves that are reflected and received from the inside of the chamber 10 (S803). For example, the monitoring device 100 may repeatedly measure state data according to a predetermined period or a plurality of measurement trigger signals indicated to the monitoring device 100. For example, the predetermined period may be several seconds or tens of seconds. For example, the measurement trigger signal may be generated by the control unit (14) of the monitoring device 100 and transmitted to the signal processing unit 120, or received from an external device through the communication unit 130 and then transmitted to the signal processing unit 120. Whenever the signal processing unit 120 receives a measurement trigger signal, the monitoring device 100 may measure state data.

Here, the monitoring device 100 may repeatedly measure the state data according to a predetermined period or a plurality of measurement trigger signals indicated to the monitoring device 100 while being attached to the outside of the chamber, but it is not limited thereto. The monitoring device 100 may repeatedly measure the state data by allowing it to be detached from the chamber 10 and then be attached thereto according to a predetermined period or a plurality of measurement trigger signals directed by the monitoring device 100. Alternatively, the monitoring device 100 may repeatedly measure the state data according to a predetermined period while being attached to the outside of the chamber, and in some cases, the monitoring device 100 may measure the state data by allowing it to be detached from the chamber 10 and then reattached thereto periodically. In this case, the monitoring device 100 may measure the state data based on the received measurement trigger signal after reattaching the monitoring device 100 to the chamber 10, or measure the state data by attaching the monitoring device 100 to the chamber 10 to allow the measurement trigger signal to be transmitted to the signal processing unit 120.

In this case, the state similarity pattern described later may be measured according to the state similarity data measured before the detachment. In addition, after correcting the measurement error due to the detachment of the monitoring device 100, the state similarity pattern may be measured according to the state similarity data measured before the detachment. Meanwhile, the method of correcting the measurement error due to detachment will be described in detail in Embodiment 5 below.

The monitoring device 100 may calculate the similarity between the reference state data and the state data obtained according to Embodiment 1 (S805). Herein, the similarity may be calculated according to Embodiment 2. In addition, the similarity may be calculated in real time or immediately when the state data is acquired according to a predetermined period or a plurality of measurement trigger signals indicated to the monitoring device 100. For example, the monitoring device 100 may measure the state data while being attached to the outside of the chamber 10, and calculate the similarity between the measured state data and the reference state data according to the predetermined period or the plurality of measurement trigger signals indicated to the monitoring device 100. In addition, the monitoring device may generate a plurality of pieces of state similarity data using the similarities calculated according to the predetermined period or the plurality of measurement trigger signals indicated to the monitoring device 100. A single piece of state similarity data may include a similarity value between the state data corresponding to a single time point and the reference state data.

The monitoring device 100 may form a plurality of similarity patterns using the plurality of pieces of state similarity data (S807). For example, as may be seen in FIG. 7, a similarity pattern of a process cycle unit may be obtained using a state similarity graph, which is a set of the plurality of pieces of state similarity data. In other words, the monitoring device 100 may determine a plurality of state similarity patterns of a process cycle unit by determining a state similarity pattern of a process cycle unit in a state similarity graph for a set of state similarity data.

The monitoring device 100 may predict the time point of abnormal operation of the chamber 10 using the plurality of state similarity patterns. For example, the monitoring device 100 performs graph fitting for the plurality of state similarity patterns (S809) and may predict the time point of the abnormal operation of the chamber 10 using a fitted graph and a similarity threshold (S811). The specific execution process of steps S809~S811 will be described in detail in Embodiment 3-2.

Meanwhile, the monitoring device 100 may determine whether the chamber is operating normally using the plurality of state similarity patterns. For example, the monitoring device 100 compares the most recent state similarity pattern among the formed state similarity patterns with a comparison state similarity pattern that is not the most recent state similarity pattern (S813), and determine whether the chamber 10 is operating normally based on the comparison result value (S815). The specific execution process of steps S813~S815 will be described in detail in Embodiment 3-3.

Below, the process of finding the state similarity pattern in step S807 based on the plurality of pieces of state similarity data in step S805 and thus forming the plurality of state similarity patterns will be described.

(1) Method of Finding State Similarity Pattern by Comparison with Process Section Data

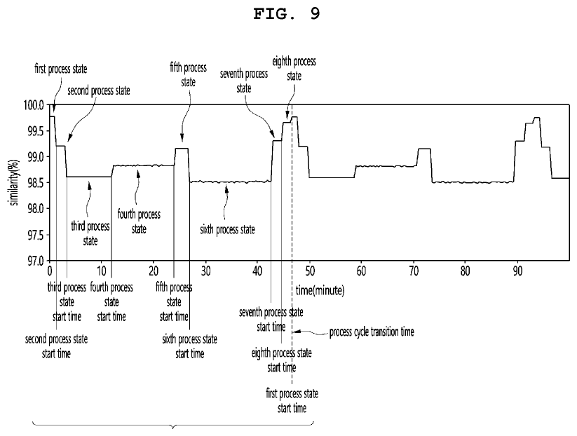

The monitoring device 100 may generate a state similarity graph based on the plurality of pieces of state similarity data as described in step S805. Then, the state similarity graph is compared with the process duration data, to recognize the transition time points between each process. For example, a state similarity graph appearing when a plurality of processes included in a process cycle are performed is shown referring to FIG. 9. The plurality of pieces of state similarity data may be measured within each process, and the state similarity graph may be drawn based on this. Meanwhile, the actual state similarity graph may take various forms. In particular, referring to the 4th process state and the 6th process state, the same similarity is not measured in one process state, but different similarities are measured as the process progresses.

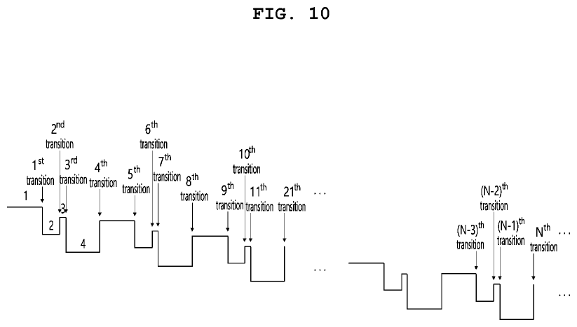

However, in the present disclosure, for the convenience of explanation, the state similarity graph is schematically explained as a square graph as in FIGS. 10 to 12. In addition, as in FIG. 9, the number of process states included in one process cycle may be 8 or more, and for the convenience of explanation, as in FIGS. 10 to 12, it is assumed that one process cycle has 4 process states. However, it is clear that the number of process states included in one process cycle is not limited to 4 or 8. In other words, the number of processes included in the process cycle according to the embodiment of the present disclosure is not limited to a specific number, and two or more processes are determined according to process to be included in one process cycle without limitation.

While the monitoring device 100 calculates the similarity according to a predetermined period or plurality of measurement trigger signals indicated to the monitoring device 100, the process cycle is performed repeatedly several times, and while the process cycle is performed repeatedly several times, a time point at which each process is switched may be recorded in the process section data. Meanwhile, this process duration data is stored in the storage unit 150 of the monitoring device 100 or stored in an external storage device such as a USB, so that the monitoring device 100 may read the process section data stored in the external storage device.

The monitoring device 100 may match the time point at which each process is switched, stored in the process duration data, with the state similarity graph, to find the time point at which each process is switched and a time point at which one process cycle ends and the next process cycle starts in the state similarity graph. For example, as may be seen in FIG. 9, it may find the time point at which each process state is switched and the time point at which the process cycle is switched by matching the start time of each process state recorded in the process section data with the state similarity graph.

In addition, the monitoring device 100 may determine the state similarity graph as a state similarity pattern, during the time when one process cycle starts and ends in the above-described method. That is, when the process cycle is performed repeatedly multiple times, the state similarity graph for each process cycle may be recognized as each state similarity pattern. Meanwhile, the state similarity pattern may include an idle duration included between each process cycle or before the first process cycle. For example, the state similarity pattern may mean a state similarity graph during an idle duration and a process cycle occurring immediately after the idle duration. In addition, the idle duration may mean that the chamber is in an idle state.

Hereinafter, for convenience of explanation, unless otherwise specified, it will be appreciated that the state similarity pattern means a state similarity graph during a process cycle that includes an idle duration and a plurality of processes occurring immediately after the idle section. In addition, in the following description, for convenience of explanation, it is described that the process cycle includes the first process to the fourth process, but any one of the first process to the fourth process may mean an idle duration or an idle state. For example, the first process may mean an idle duration or an idle state. In addition, in the present disclosure, for convenience of explanation, it is described that the process cycle includes the first process to the fourth process, but it is not limited thereto, and the number of processes that may be included in the process cycle may vary depending on the type of work performed by the chamber 10.

When the monitoring device 100 compares the process section data and the state similarity graph whenever at least one state similarity data is determined to complete each process cycle, the state similarity graph corresponding to each process cycle may be read as the similarity pattern to be stored in the storage unit 150.

The monitoring device 100 performs the above-described method each time the process cycle is repeated and stores the recognized state similarity pattern in the storage unit 150, thereby collecting a plurality of state similarity patterns.

### (2) a Method of Determining the State Similarity Pattern by Collecting State Similarity Data Until N Transition States Occur

Another method of determining a state similarity pattern will be described.

Referring to FIG. 10, the monitoring device 100 may repeatedly calculate the similarity according to a predetermined period or a plurality of measurement trigger signals indicated to the monitoring device 100 until N transitions occur, and generate a plurality of pieces of state similarity data using the calculated similarity. In addition, the monitoring device 100 may generate a state similarity graph based on the plurality of pieces of state similarity data.

Herein, N may be a value preset in the monitoring device 100. For example, the monitoring device 100 generates state similarity data until 100 transition states occur, and continuously draws the state similarity data, and when a similar similarity trend appears in unit of 4 intervals, the monitoring device 100 may determine that there are 4 processes and then determine state similarity patterns corresponding to processes 1 to 4. In this case, the monitoring device 100 may determine state similarity patterns in unit of 4 transitions, form the plurality of state similarity patterns, and store them in the storage unit 150. The monitoring device 100 may generate state similarity data based on the similarity calculated according to a predetermined period or the plurality of measurement trigger signals indicated to the monitoring device 100, and repeatedly determine state similarity patterns in unit of 4 transitions and repeatedly store them in the storage unit 150.

### 3. Embodiment 3-2: Method of Predicting a Time of Abnormal Operation of Chamber Using State Similarity Pattern

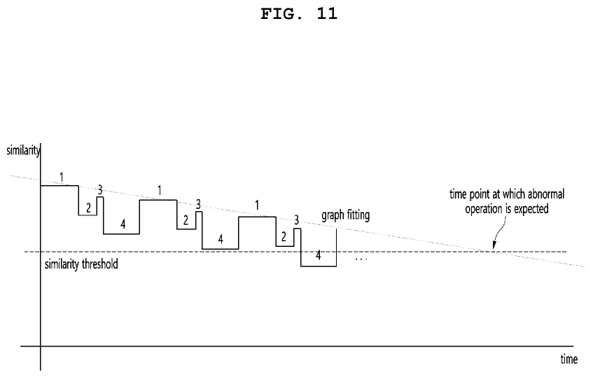

Hereinafter, with reference to FIG. 11, a method of predicting a time point of an abnormal operation of a chamber 10 by a monitoring device 100 will be described.

Referring to FIG. 11, the monitoring device 100 may repeatedly calculate the similarity according to a predetermined cycle or the plurality of measurement trigger signals directed by the monitoring device 100, thereby generating a plurality of pieces of state similarity data. In addition, the monitoring device 100 may repeatedly generate a state similarity graph based on the plurality of pieces of state similarity data.

In addition, the monitoring device 100 may obtain the plurality of state similarity patterns according to Embodiment 3-1. Referring to FIG. 11, it may be shown that the plurality of state similarity patterns is repeated according to similar patterns. However, it may be shown that the absolute state similarity data of the plurality of state similarity patterns is gradually decreasing. In other words, in FIG. 11, the value of the state similarity data of the first process included in the first state similarity pattern is higher than the value of the state similarity data of the first process included in the second state similarity pattern. Similarly, the value of the state similarity data of each of the second to fourth processes included in the first state similarity pattern is higher than the value of the state similarity data of each of the second to fourth processes included in the second state similarity pattern. However, the first state similarity pattern and the second state similarity pattern may show similar/same tendencies. That is, for example, the differences between the state similarity data values of each of the first to fourth processes included in the state similarity pattern and the state similarity data values of each of the second to fourth processes included in the second state similarity pattern corresponding thereto may be the same/similar.

In addition, the monitoring device 100 may configure at least one reference point in each of the plurality of state similarity patterns acquired according to Embodiment 3-1. For example, referring to FIG. 11, one may be selected from among the process states (i.e., idle duration and processes) included in each process cycle, and at least one reference point may be determined in the selected process state (idle duration or process). Herein, at least one reference point in each state similarity pattern may be selected within the same process state (e.g., the same idle duration). In addition, at least one reference point in each state similarity pattern may be selected as the same corresponding time point within the same process state.

For example, the monitoring device 100 may select a center point of the first process state (e.g., idle duration) of each state similarity pattern, and perform graph fitting using an exponential function in the form of A exp (−bx)+C by connecting the center points of each state similarity pattern in the first process state. Meanwhile, the example of performing graph fitting is not limited to the above-described content. For example, the first process state may be replaced by any process among the second process state to the Nth process state, and the center point may be replaced by a starting point, an end point, or a specific point in the selected process state. In addition, the graph fitting performed by the monitoring device 100 is not limited to graph fitting using an exponential function, and may be applied to various graph fitting methods such as graph fitting using a linear function, graph fitting using a polynomial function, and graph fitting using a logarithmic function. In addition, the function used in the above graph fitting may use time as a variable. In other words, since the state similarity graph is generated based on the similarities between the state data of the chamber 10 measured over time and the reference state data and the plurality of pieces of state similarity data generated using the similarities, the function used for graph fitting may be used with a function over time.

In addition, although in the above-described example, it is described that one time point is selected from one selected process state, a plurality of time points may be selected. For example, graph fitting may be performed by connecting the start point and the end point of the first process state of each state similarity pattern. In addition, in the above-described example, not only one process state is selected, but a plurality of process states may be also selected. For example, the monitoring device 100 may perform graph fitting by connecting the start point of the first process state of each state similarity pattern and the start point of the second process state, and may perform graph fitting by connecting the start point and the end point of the first process state of each similarity pattern with the start point and the end point of the second process state.

The monitoring device 100 may compare the fitted graph with the similarity threshold when the graph fitting is performed. Then, it may determine the point at which the fitted graph and the similarity threshold meet as a time point at which abnormal operation of the chamber 10 is predicted, and notify the user through the communication unit 130 or the output unit (not shown) that the abnormal operation of the chamber 10 is predicted to occur at that time point. That is, the monitoring device 100 may predict the time points when the value of the fitted graph becomes lower than the similarity threshold, as the time point of abnormal operation of the chamber 10. Therefore, the monitoring device 100 may determine the first time point at which the value of the fitted graph becomes lower than the threshold similarity, as a time point at which the abnormal operation of the chamber 10 is predicted.

Meanwhile, the similarity threshold may be configured differently according to the specifications of the chamber 10 and the process margin.

Meanwhile, the graph fitting of FIG. 11 and the prediction of the time point of the abnormal operation may be continuously performed at regular intervals. Referring to FIG. 7, considering the state similarity graph in the time point when the monitoring device 100 starts monitoring the chamber 10 or the time area immediately after PM is started, it may be seen that the slope of the state similarity graph is steep. Therefore, when predicting the time point of the abnormal operation of the chamber 10 in the time point at which the monitoring device 100 starts monitoring the chamber 10 or time area immediately after PM is started, the time may be predicted to be relatively early. However, it may be seen that the slope of the state similarity graph becomes gentler when the operation of the chamber 10 stabilizes as it moves from the initial region to the progress region where the chamber 10 operates. Therefore, the time point of the abnormal operation of the chamber 10 may be predicted to be relatively slow as it moves from the initial region to the progress region where the chamber 10 operates. In addition, since the process may malfunction due to a specific event while the chamber 10 is operating, and the chamber 10 or the process may change unexpectedly due to a specific event, there is an aspect that it is impossible to predict how the change will continuously occur. Therefore, the monitoring device 100 must continuously perform graph fitting to predict the time point of the abnormal operation of the chamber 10 in order to increase the accuracy of the time prediction of the abnormal operation.

Meanwhile, the period in which the monitoring device 100 performs graph fitting to predict the abnormal operation point of the chamber 10 may be several seconds or several tens of seconds. Alternatively, the period in which the monitoring device 100 performs graph fitting to predict the abnormal operation point of the chamber 10 may be one day or several days. For example, the monitoring device 100 may perform graph fitting to predict the abnormal operation point of the chamber 10 every time it measures the similarity according to a predetermined period or a plurality of measurement trigger signals indicated to the monitoring device 100, and perform graph fitting to predict the time point of the abnormal operation of the chamber 10 every time one state similarity pattern is acquired.

### 4. Embodiment 3-3: Method of Determining Whether a Chamber is Operating Normally Using a State Similarity Pattern

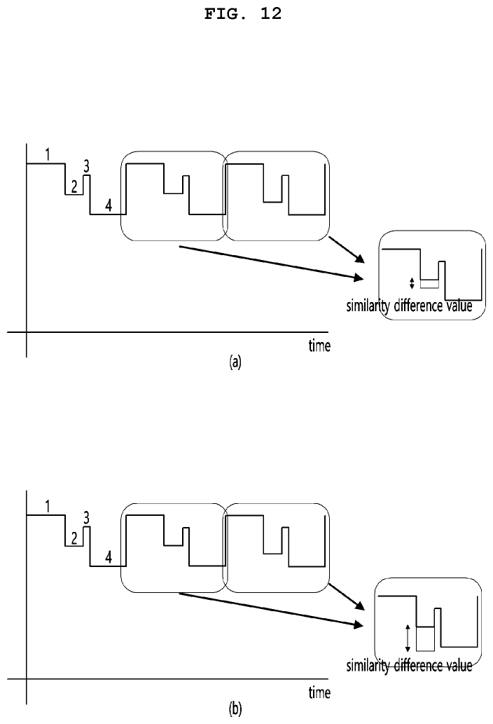

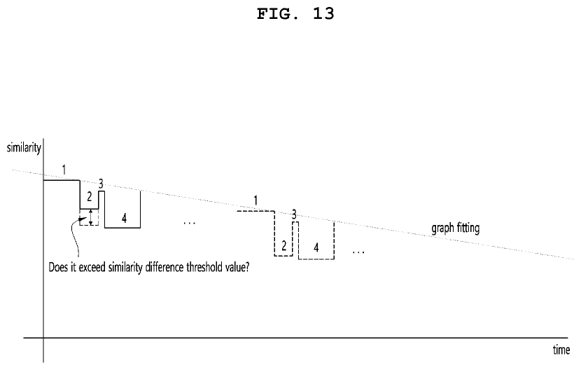

Hereinafter, with reference to FIGS. 12 and 13, a method for determining whether a chamber 10 is operating normally will be described. In order to determine whether a chamber 10 is operating normally, two state similarity patterns of a plurality of state similarity patterns acquired by the monitoring device 100 may be compared.

Herein, in order to determine the current state of the chamber, the monitoring device 100 may determine one of the two state similarity patterns as the most recently acquired state similarity pattern.

The other state similarity pattern may be selected as any one of the state similarity patterns other than the most recent state similarity pattern among a plurality of similarity patterns. Hereinafter, the other state similarity pattern for comparison with the most recent state similarity pattern is called a comparison state similarity pattern.

### (1) Method of Selecting a Comparative Similarity Pattern

The comparative state similarity pattern may be the state similarity pattern obtained initially after the monitoring device 100 measures the similarity of the chamber 10. The initial state similarity pattern may be the state similarity pattern when the state of the chamber 10 is the best since the monitoring device 100 starts measuring the similarity, so that the best state of the chamber 10 is compared with the current state of the chamber 10, thereby finding out how the current state of the chamber 10 deteriorates.

Meanwhile, the comparison state similarity pattern may be an average state similarity pattern calculated by obtaining the average of the state similarity patterns from the initial state similarity pattern to the Pth state similarity pattern. As shown in FIG. 7, since the similarity decreases relatively rapidly immediately after the monitoring the state of the chamber 10 is started, it is possible to find out how much the current state of the chamber 10 has deteriorated on average, by using, as the comparison state similarity pattern, the average state similarity pattern obtained by calculating the average of state similarity pattern when the chamber 10 was stabilized to some extent and state similarity pattern when the chamber 10 was in the best condition.

In addition, the comparison state similarity pattern may be the state similarity pattern closest to the most recent similarity pattern. That is, it may be the second most recent state similarity pattern. Since the monitoring device 100 repeatedly determines whether the chamber 10 is operating normally whenever a state similarity pattern is acquired, when the second most recent state similarity pattern is used as the comparison state similarity pattern, it is easy to find out at what time point a sudden failure or abnormal state of the chamber 10 occurred.

Alternatively, the comparison state similarity pattern may be selected as any state similarity pattern among the state similarity patterns, other than the most recent state similarity pattern.

(2) Method of Determining Whether Chamber 10 is Operating Normally by Comparing the Comparison State Similarity Pattern with the Most Recent State Similarity Pattern

The monitoring device 100 compares the state similarity data of the comparison state similarity pattern with the state similarity data of the most recent state similarity pattern for each process state, to recognize that an abnormal factor (e.g., failure, etc.) has occurred in a process with state similarity data in which the difference is greater than a predetermined similarity difference threshold value.

That is, the method of recognizing the abnormal operation of the chamber described with reference to FIG. 12 may mean a method of recognizing the abnormal operation of the chamber by comparing the relative size difference between each state similarity data included in the most recent state similarity pattern and each state similarity data included in the comparison state similarity pattern.

Herein, the similarity difference threshold value that serves as the criterion for comparison is configured in the following manner, and whether the chamber 10 is operating normally may be determined in the following manner.

### 1) Method of Determining Whether Chamber 10 is Operating Normally Using Different “Similarity Difference Threshold”

The similarity difference threshold values may need to be set different from each other in order to determine whether a chamber 10 is operating normally based on the comparison state similarity pattern. For example, as may be seen in FIG. 7, even when the chamber 10 is operating normally, the similarity may gradually decrease as the process cycle is repeated.

Therefore, even in the case that the chamber 10 is operating normally, when the comparison state similarity pattern is the initial state similarity pattern, the difference between the most recent state similarity pattern and the state similarity data will be relatively large, and when the comparison state similarity pattern is the second most recent state similarity pattern, the difference between the most recent state similarity pattern and the state similarity data will be relatively small. Therefore, the configured similarity difference threshold value needs to be configured differently from each other depending on the comparison state similarity pattern.

FIG. 12(a) shows that the similarity difference threshold value is configured when the second most recent state similarity pattern is a comparison state similarity pattern, and FIG. 12(b) shows the similarity difference threshold value is configured when the initial state similarity pattern is a comparison state similarity pattern.

For example, referring to FIG. 12(a), when the second most recent state similarity pattern is a comparison state similarity pattern, the similarity difference threshold value is configured to a relatively small value, so that the chamber 10 may be classified as being in abnormal operation even if the difference between the state similarity data of the comparison state similarity pattern and the most recent state similarity pattern is small. Meanwhile, referring to FIG. 12(b), when the initial state similarity pattern is a comparison state similarity pattern, the similarity difference threshold value is configured to a relatively large value, so that the chamber 10 may be classified as being in abnormal operation when the difference between the similarity data of the comparison state similarity pattern and the most recent state similarity pattern is relatively large.

Therefore, if the comparison state similarity pattern is not fixed to any one of the examples described above but is changed, a plurality of similarity difference threshold values should be configured. For example, when the comparison state similarity pattern is selected as the initial state similarity pattern, the second most recent state similarity pattern, or the average state similarity pattern depending on the state measurement situation of the chamber 10, a plurality of similarity difference threshold values should be configured according to each state similarity pattern that may be selected. In addition, the monitoring device 100 should determine whether the chamber 10 is operating normally using the similarity difference threshold value corresponding to the selected state similarity pattern.

For example, the monitoring device 100 may determine the similarity difference threshold value according to the pattern interval between the selected comparison state similarity pattern and the most recent state similarity pattern. For example, the monitoring device 100 may determine the similarity difference threshold value according to the number of state similarity patterns (i.e., pattern interval) included between the selected comparison state similarity pattern and the most recent state similarity pattern. Alternatively, the monitoring device 100 may determine the similarity difference threshold value according to the time interval between the selected comparison state similarity pattern and the most recent state similarity pattern.

Herein, the similarity difference threshold value may be selected from among a plurality of similarity difference threshold values configured according to the time interval or pattern interval. Alternatively, the similarity difference threshold value may be calculated through a specific algorithm or a specific formula for the time interval or pattern interval.

### 2) Method of Determining Using One “Similarity Difference Threshold Value”

When one similarity difference threshold value is configured in the monitoring device 100 and a comparison state similarity pattern is selected, the selected comparison state similarity pattern and the most recent state similarity pattern may be approximately corrected. In addition, whether the chamber 10 is normally operated may be determined by comparing the corrected most recent state similarity pattern and the selected comparison state similarity pattern.

For example, as shown in FIG. 13, the most recent state similarity pattern may be corrected by utilizing the fitted graph obtained in the execution process of Embodiment 3-2 or a function corresponding to the fitted graph (using a time variable).

FIG. 13 shows that the comparison state similarity pattern is selected as an initial state similarity pattern. Referring to FIG. 13, the monitoring device 100 may correct the most recent state similarity pattern to be generally similar to the initial state similarity pattern using the fitted graph or corresponding function. For example, the most recent state similarity pattern may be moved to the time point corresponding to the initial state similarity pattern according to the fitted graph or corresponding function. Alternatively, it may be generally corrected similarly to the most recent state similarity pattern, by adding the difference between the reference points (e.g., the start point or the end point or the center point of each selected process) used for graph fitting or function derivation within the most recent state similarity pattern and the initial state similarity pattern to the state similarity data included in the most recent state similarity pattern.

The monitoring device 100 calculates the difference between the state similarity data of the most recent corrected state similarity pattern and the initial state similarity pattern, and recognize that the abnormal operation of the chamber 10 has occurred in the process state including the state similarity data having a difference greater than the configured similarity difference threshold value.

Meanwhile, although above-described embodiment is performed assuming that the comparison state similarity pattern is the initial state similarity pattern, the principle of the above-described embodiment may be applied even when the comparison state similarity pattern is an arbitrary state similarity pattern. For example, the monitoring device 100 may compare the comparison state similarity pattern and the most recent state similarity pattern after correcting the most recent state similarity pattern to correspond to an arbitrary state similarity pattern using a fitted graph or a corresponding function. In addition, the monitoring device 100 may recognize that the abnormal operation of the chamber 10 has occurred in the process state including the state similarity data in which the difference between the state similarity data is greater than a configured similarity difference threshold value.

Meanwhile, in the above-described embodiment, the period for comparing the most recent state similarity pattern with the comparison state similarity pattern may be the same as the period for forming one state similarity pattern. For example, the monitoring device 100 may select the comparison state similarity pattern whenever one state similarity pattern is acquired, to determine whether the chamber 10 is operating normally.

### 5. Experimental Data

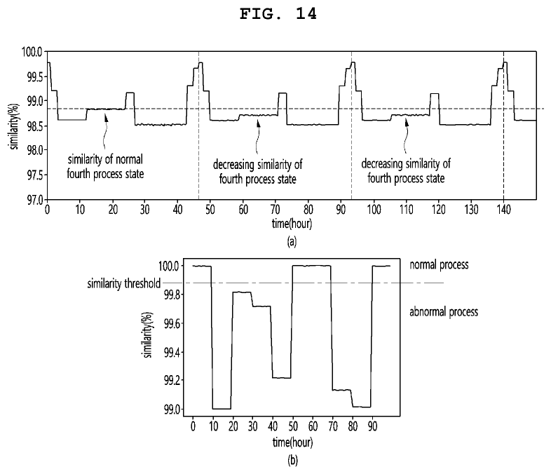

FIG. 14 shows the consistency and accuracy of whether the actual chamber 10 was abnormal, when the monitoring device 100 determined whether the chamber 10 was operating abnormally using the state similarity pattern according to the above-described Embodiment 3. Referring to FIG. 14(a), as a result of continuously measuring the similarity data of the 4th process state while going through the process cycle based on the state similarity data of the 4th process state when the chamber was normal, it was found that the state similarity data of the 4th process state was significantly different from the state similarity data of the 4th process state when it was normal. Accordingly, as a result of actually checking the 4th process, it was confirmed that there was a problem in the 4th process.

FIG. 14(b) shows the state similarity data measured while artificially changing the process state every 10 minutes. With respect to FIG. 14(b), although the state similarity data was measured higher than the similarity threshold in the process where the chamber was initially normal, when the process state was artificially made abnormal 10 minutes later, the state similarity data was measured significantly lower than the similarity threshold.

In this way, when the process state was artificially changed at 10-minute intervals, it was confirmed that the state similarity data continuously changed, and the state similarity data significantly decreased in the duration where abnormal changes were made.

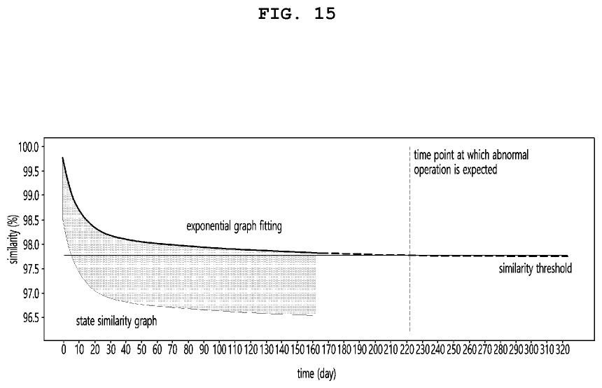

In addition, FIGS. 15 to 17 are intended to describe the accuracy of predicting the time point of the abnormal operation of the chamber 10 according to the above-described Embodiment 3.

FIG. 15 shows graph fitting performed using the Exponential function on the state similarity graph according to Embodiment 3.

FIG. 15 shows that the graph fitting is performed based on the state similarity graph drawn by measuring state similarity data for about 160 to 170 days, thereby comparing it with the similarity threshold to predict the time point at which abnormal operation is predicted.

As a result of the calculation, it was predicted that the chamber to be measured would become abnormal at the 221.7th day. However, a significant process difference was found at the 222nd day of measurement in the chamber to be measured, and accordingly PM was performed.

According to the results of the experiment, it may be accurately predicted that the chamber will perform abnormal operation at least 2 months before the chamber performs abnormal operation. Accordingly, it was confirmed that the advance preparation to perform immediate PM is possible in case that the chamber performs abnormal operation.

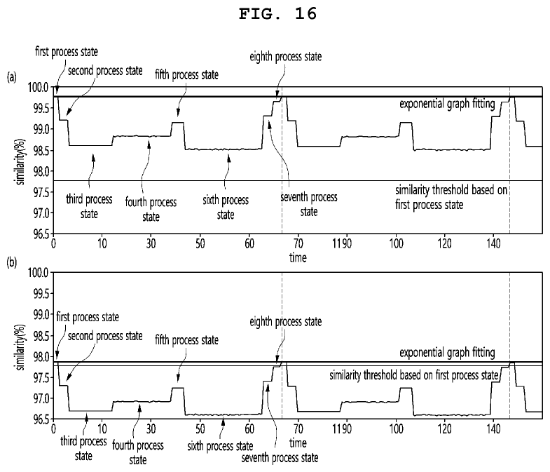

FIG. 16 shows how close the state similarity graph and graph fitting using the Exponential function to the similarity threshold when measurements for the chamber continue. FIG. 16(a) is a graph of the first day of measurements for the target chamber, and FIG. 16(b) is a graph of the 160th day of measurements for the target chamber.

In FIG. 16, the graph fitting was performed based on the first process state. In addition, referring to FIG. 16(a), it may be seen that the fitted graph is significantly different from the similarity threshold. However, referring to FIG. 16(b), it may be seen that the fitted graph is significantly less different from the similarity threshold.

In other words, as the measurement time passes, the time point at which the fitted graph meets the similarity threshold may be accurately measured, and accordingly, the time point at which the target chamber will perform abnormal operation may be predicted.

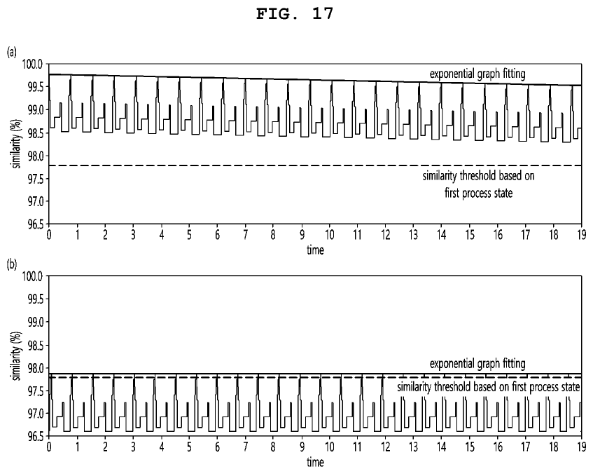

FIG. 17 shows a wide view with changing an X-axis scale of FIG. 16 from “minutes” to “hours”. FIG. 17(a) is a graph of the first day of measurement for the target chamber, and FIG. 17(b) is a graph of the 160th day of measurement for the target chamber. Referring to FIG. 17, the difference in the fitted graph described through FIG. 16 and the relationship between the fitted graph and the similarity threshold may be seen more clearly.

### Embodiment 4: Method of Determining and Predicting the Process State of a Chamber Using Reference State Data of Each Process

Hereinafter, a method of determining whether a chamber is operating normally or predicting the time of abnormal operation of a chamber with respect to Embodiment 4 is explained differently from Embodiment 3.

In Embodiment 4, the monitoring device 100 generates reference state data for each process performed in the chamber. In addition, the monitoring device 100 determines the process currently performed in the chamber using the process duration data, loads the reference state data of the determined process, and calculates the similarity between the loaded reference state data and the currently measured state data. In addition, the monitoring device 100 determines abnormal operation of the chamber or predicts the time of abnormal operation of the chamber based on the calculated similarity.

In Embodiment 4, for the convenience of explanation, it is exemplified that there are five process states that are performed in the chamber. That is, it is exemplified that one process cycle consists of five processes. However, as described above, it should not be interpreted that Embodiment 4 is limited to five processes in the process cycle, and it should be noted that when more than one process is performed in one process cycle, Embodiment 4 may be applied.

Hereinafter, the operation in this embodiment 4 will be described in more detail.

### 1. Embodiment 4-1: Method of Determining Whether the Chamber is Operating Normally Using Reference State Data of Each Process

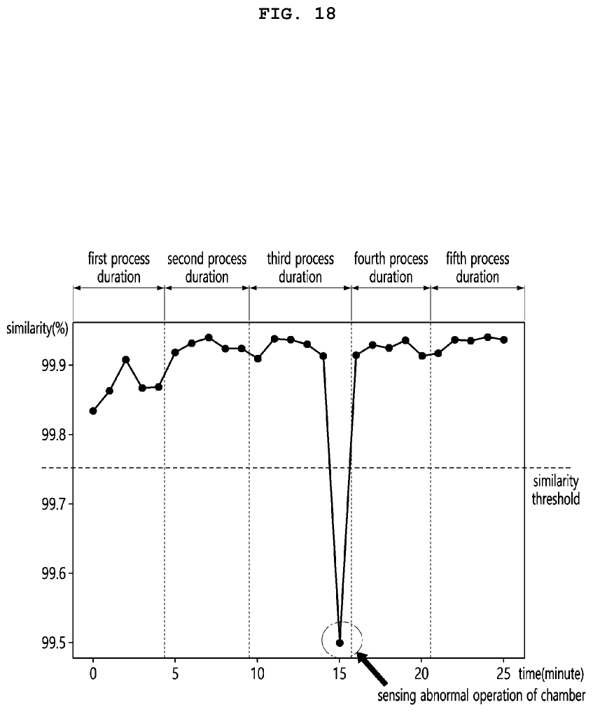

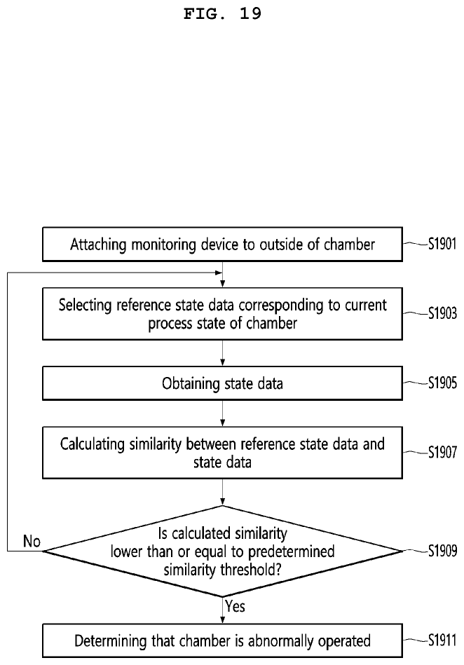

FIGS. 18 and 19 illustrate a method of determining whether a chamber is operating normally using process-specific reference state data according to Embodiment 4-1.

In Embodiment 4-1, as seen in FIG. 18, the monitoring device 100 identifies the process duration or process state of the chamber 10 using process duration data. The monitoring device 100 measures the state data and compares the reference state data of the identified process with the measured state data to calculate the similarity.

Here, the process duration data includes data that may identify the start and end times of each process. Alternatively, the process duration data includes data that may identify the length or time of the duration in which each process is performed. For example, the monitoring device 100 may use the process duration data to identify the order in which the processes are performed within the process cycle and the time duration in which each process is performed. Accordingly, the monitoring device 100 recognizes each process and the transition times between processes through the process duration data as described above, and compares the start time of the process cycle with the transition time between the processes, to identify the process being performed in the chamber 10 at the current time. Accordingly, the monitoring device 100 may select the reference state data of the identified process and compare it with the state data at the current time. In other words, the monitoring device 100 recognizes a time point when the process is changed using the process section data, and changes the reference state data to the reference state data of the changed process based on the time point while comparing it with the state data measured periodically/non-periodically, thereby calculating the similarity.

When the process is being performed normally, the similarity between the reference state data of the current process and the state data measured by the monitoring device 100 will be very high. However, when the process is being performed abnormally or there is a problem with the chamber 10, the similarity between the reference state data of the current process and the state data measured by the monitoring device 100 will be relatively low. Using this, it is possible to identify whether the chamber 10 is operating abnormally in Embodiment 4-1.

For example, referring to FIG. 18, in the first process duration, the similarity between the reference state data of the first process and the state data measured by the monitoring device 100 in the first process duration is measured; in the second process section, the similarity between the reference state data of the second process and the state data measured by the monitoring device 100 in the second process duration is measured; and in the third process section, the similarity between the reference state data of the third process and the state data measured by the monitoring device 100 in the third process duration is measured.

In addition, in the 4th process duration, the similarity between the reference state data of the 4th process and the state data measured by the monitoring device 100 in the 4th process duration is measured, and in the 5th process duration, the similarity between the reference state data of the 5th process and the state data measured by the monitoring device 100 in the 5th process duration is measured.

Referring to FIG. 18, a similarity of 99.8% or more, which is close to 100%, was calculated in the first process section, the second process section, the fourth process section, and the fifth process section, which indicates that the chamber 10 is performing normal operations in the first and second processes. However, it may be seen that a similarity lower than the similarity threshold was calculated in at least a part of the third process section, which indicates that the chamber 10 is performing abnormal operations in the third process.

Now, referring to FIGS. 18 and 19, a method for determining whether the chamber 10 is operating abnormally will be described in detail. According to FIGS. 18 and 19, a monitoring device 100 may be attached to the outside of the chamber (S1901). For example, the monitoring device 100 may be attached to the viewport 11 of the chamber 10. Then, the monitoring device 100 determines the process currently being performed in the chamber based on the process duration data. For example, referring to FIG. 18, the monitoring device 100 selects the reference state data of the first process, when it is determined that the current time point is included in the first process duration based on the process duration data. The monitoring device 100 selects the reference state data of the second process when the current time point is included in the second process duration based on the process duration data, and selects the reference state data of the third process when the current time point is included in the third process duration (S1903). In addition, the monitoring device 100 transmits radio waves having a specific frequency range into the inside of the chamber 10, and may obtain the state data of the chamber 10 based on the radio wave reflected and received from the inside of the chamber 10 (S1905). Here, since the method of obtaining the state data of the chamber 10 has already been explained through Embodiment 3 and S803 of FIG. 8, a detailed description is omitted.

The above monitoring device 100 may calculate the similarity between the selected reference state data and the acquired state data (S1907). Herein, since the method for calculating the similarity has also been described through Examples 2 to 3 and S805 of FIG. 8, a detailed description thereof will be omitted.

The monitoring device 100 determines whether the calculated similarity is lower than or equal to the predetermined similarity threshold (S1909). When the calculated similarity exceeds the predetermined similarity threshold, the monitoring device 100 determines that the process within the chamber 100 is being performed normally, and repeats the process from S1903.

When the calculated similarity is lower than or equal to the predetermined similarity threshold, it is determined that the chamber 10 is abnormally operated, and the user may be notified to take appropriate action (S1911).

### 2. Embodiment 4-2: Method of Predicting Abnormal Operation Point of Chamber Using Reference State Data of Each Process

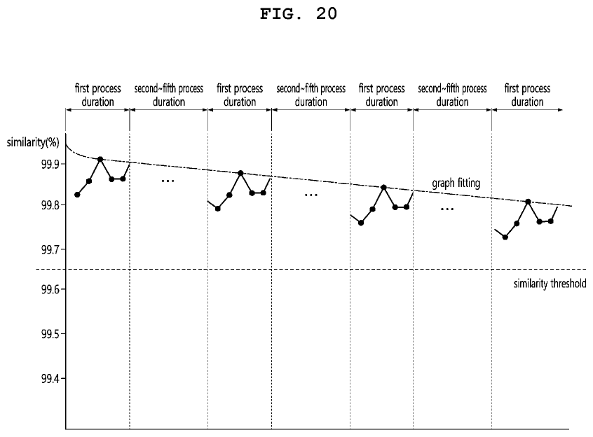

FIGS. 20 to 22 illustrate a method for predicting abnormal operation point of chamber using reference state data of each process according to Embodiment 4-2. Referring to FIG. 20, as described in Embodiment 3, even when the similarity between the same reference state data (e.g., the reference state data of the first process) in the same process (e.g., the first process) and the state data measured by the monitoring device 100 is measured, it may be seen that the similarity is gradually decreasing.

That is, even when the similarity between the state data measured at the time and the reference state data for the process is calculated by using the reference state data for the process at the time when the monitoring device 100 measures the state data, the similarities for the same process may gradually decrease.

Accordingly, Embodiment 4-2 considers on a method of predicting the time point when the chamber 10 will operate abnormally by measuring the similarity based on at least one reference point within the same process while a plurality of process cycles is repeated. That is, it considers a method of predicting the time point when the chamber 10 will operate abnormally by performing graph fitting based on at least one reference point within the same process duration without using a similarity pattern like Embodiment 3-2.

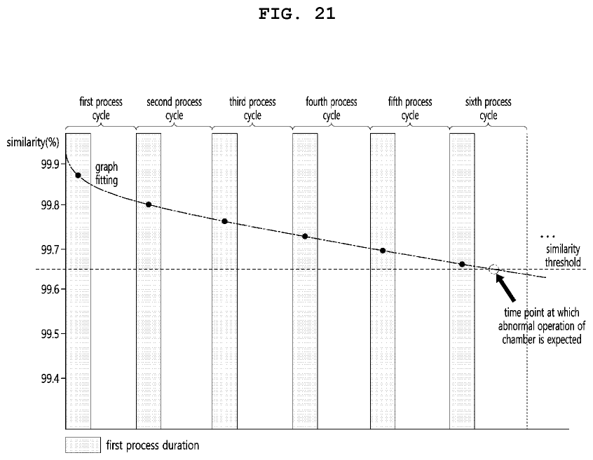

FIG. 21 shows an example in which a monitoring device 100 measures state data in a first process within each cycle during a plurality of process cycles and measures the similarity between the measured state data and reference state data of the first process.

Referring to FIG. 21, the monitoring device 100 measures similarities in the same first process and performs graph fitting on the similarities as in Embodiment 3-2. In addition, the monitoring device 100 may determine the point in time when the fitted graph and the similarity threshold meet as the time point when abnormal operation of the chamber is predicted. Meanwhile, the graph fitting may be performed every time the similarity is measured in the first process of each cycle. Alternatively, the graph fitting may be performed every time the similarity is calculated in the first process of each cycle during N cycles to calculate N similarities.

In addition, although in Embodiment 4-2, it is described that graph fitting was performed using the similarities between the process state data and state data of the first process, this is for the convenience of explanation and understanding, and it is not necessarily predicted that the graph fitting and the abnormal operation of the chamber 10 will occur based on the first process, and it is obvious to a person skilled in the art that graph fitting may be performed by selecting any one process included in the process cycle.

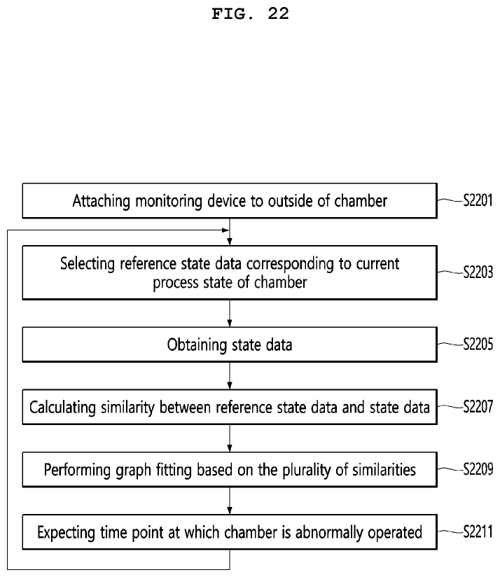

FIG. 22 is for illustrating the operation of the monitoring device 100 for predicting the abnormal operation point of the chamber according to embodiment 4-2.

Since steps S2201 to S2207 in FIG. 22 are identical to steps S1901 to S1907 of FIG. 19 related to Embodiment 4-1, a redundant description is omitted.

The monitoring device 100 determines at least one reference point and performs graph fitting using the determined at least one reference point (S2209). For example, the monitoring device 100 may select one of the process states included in each process cycle (e.g., the first process) and determine at least one reference point in the selected process state. Meanwhile, since the method of determining at least one reference point by the monitoring device 100 is described in Embodiment 3-2, a redundant description will be omitted.

In addition, the monitoring device 100 may perform graph fitting using the similarity calculated from at least one reference point of the selected process state (e.g., the first process) for each process cycle. For example, the monitoring device 100 may perform graph fitting that connects the similarities of at least one reference point included in the first process of each process cycle using a specific function. For example, the specific function may be an exponential function in the form of A exp (−bx)+C as mentioned in Embodiment 3-2, but is not limited thereto, and various functions may be used as mentioned in Embodiment 3-2. Since a specific graph fitting method may apply the graph fitting method described in Embodiment 3-2, a detailed description is omitted. The monitoring device 100 may predict the first time point at which the fitted graph value becomes less than or equal to the similarity threshold, as the time point of the abnormal operation of the chamber 10 (S2211).

Meanwhile, the graph fitting and the prediction of the time point of the abnormal operation may be continuously performed at regular intervals. Therefore, after performing S2211, the monitoring device 100 may return to S2203 and perform subsequent procedures. Since the graph fitting and prediction cycle of the time point of the abnormal operation overlap with the description of Embodiment 3-2, the description of Embodiment 3-2 is applied and a detailed description is omitted.

### Embodiment 5: Method of Correcting Measurement Error of Monitoring Device 100

### 1. Problems of Prior Art

Since a parameter (for example, S11 parameter) for measuring the frequency characteristic used for measuring the state of the chamber 10 by the monitoring device 100 according to the present disclosure is very sensitive to the position of the chamber 10 to which the monitoring device 100 is attached, there is a problem that the measured parameters are measured differently depending on the position to which the monitoring device 100 is attached.

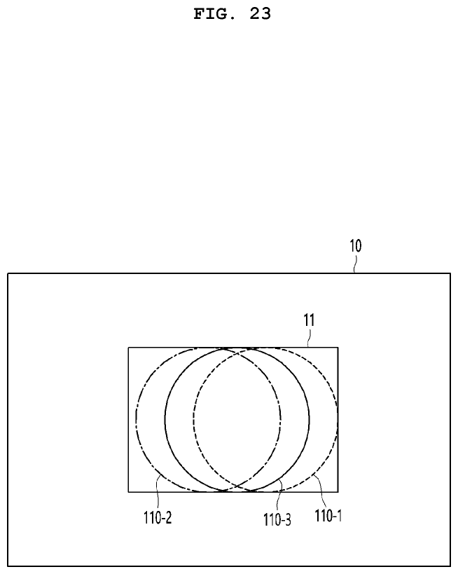

For example, referring to FIG. 23, when a parameter set (i.e., state data) for the same chamber 10 in the same state (e.g., idle state) is repeatedly measured using the same monitoring device 100, since each of a plurality of parameter sets (i.e., state data) repeatedly measured should include the same parameter values, all of the plurality of parameter sets (i.e., state data) need to indicate that the chamber 10 is always in the same state.

However, as described above, the plurality of parameter sets measured by the monitoring device 100 are measured differently depending on the relative attachment position of the monitoring device 100. For example, as shown in FIG. 23, it is assumed that the parameter sets are measured while attaching and detaching the monitoring device 100 to/from the viewport 11 of the chamber 10 in the idle state. Since the chamber 10 is in the same idle state, even when the parameter sets (i.e., state data) are measured while repeatedly attaching and detaching the monitoring device 100 to/from the viewport 11, a user expects that the parameters corresponding to the same frequency will always have the same value within the plurality of parameter sets (i.e., state data).

However, as a result of actual measurement, it was found that the first parameter value measured after attaching the antenna 110 of the monitoring device 100 to the position 110-1 in the viewport 11, the second parameter value measured after detaching the antenna 110 from the position 110-1 and reattaching it to the position 110-2, and the third parameter value measured after detaching the antenna 110 and reattaching it to the position 110-3 have different values from each other. Meanwhile, since the positions 110-1, 110-2, and 110-3 have differences enough capable of being confirmed with the naked eye in the drawing, this is for the convenience of explanation, and the differences between the center points of the positions 110-1, 110-2, and 110-3 are several mm or several um or several tens of um. In other words, even when the monitoring device 100 has a difference in the attachment location of several mm, several um, or several tens of um depending on the attachment/detachment, since the first parameter value to the third parameter value have different differences from each other, it may be seen that the measurement results of a plurality of parameter sets are significantly affected by even a slight attachment error of the monitoring device 100.

Herein, the first parameter value, the second parameter value, and the third parameter value are values for parameters corresponding to the same frequency.

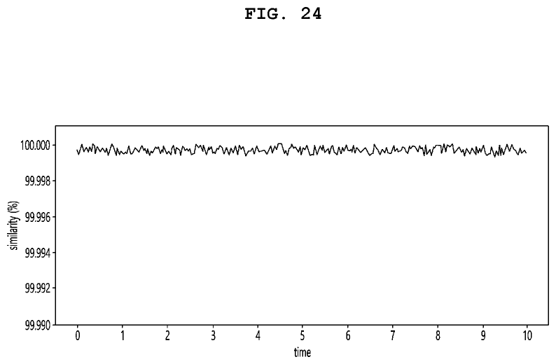

The result values for this may be seen through FIGS. 24 to 26.

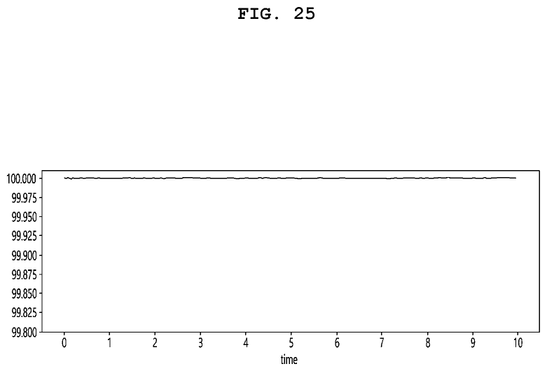

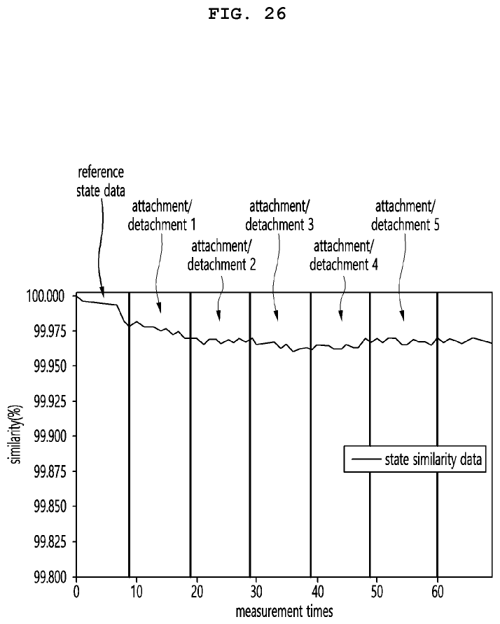

FIGS. 24 and 25 shows state similarity data generated between reference state data and state data without attaching or detaching the monitoring device 100, and FIG. 26 shows state similarity data generated by calculating the similarity between reference state data and state data of the monitoring device 100 according to the above-described Embodiment 3 while attaching or detaching the monitoring device 100 to/from the chamber 10 in an idle state, and a state similarity graph expressed using the generated state similarity data.

Referring to FIG. 24, the monitoring device 100 was attached to the chamber 10 without being detached, and then the state similarity data was measured. As seen in FIG. 24, when the state similarity data is measured multiple times in a situation where it is attached to the chamber 10, the measured state similarity data changes only within 0.001%. In other words, the difference between the measured state similarity data does not exceed 0.001%. In other words, when the state similarity data is measured multiple times in a situation where the monitoring device 100 is attached to the chamber 10, the difference in the state similarity data is so small that it may be ignored. FIG. 25 is a graph of FIG. 24 scaled down on the Y axis. Referring to FIG. 25, it may be seen that the state similarity data measured multiple times is almost constant.

Referring to FIG. 26, although the chamber 10 is in the same idle state, when the state similarity data is generated while repeating the attachment/detachment, it may be found that different state similarity data is generated each time the attachment/detachment is performed. Herein, FIG. 26 and FIG. 25 have the same Y-axis scale. Considering FIG. 26, it may be seen that the state similarity data is measured differently each time the monitoring device 100 is repeatedly attached/detached while measuring. Specifically, when the monitoring device 100 is repeatedly attached/detached while measuring, the measured state similarity data changes within a maximum of 0.03% even when the chamber 10 is in the same state. In other words, the difference between the measured state similarity data may be up to 0.03%, which shows a significant difference compared to the difference only within 0.001%.

In other words, even when the state of the chamber 10 is the same, the monitoring device 100 may determine that the state of the chamber 10 is different depending on the position where the antenna 110 is attached within the viewport 11, and thus the measurement accuracy may be reduced.

To solve this, the antenna 110 must always be attached to the same position even when the attachment and detachment of the antenna 110 is repeated within the viewport 11.

However, this is realistically very difficult. Since the attachment of the antenna 110 is done directly by a person or machine, it is realistically impossible to attach it to the same location every time without any error.

Therefore, a method of correcting measurement errors due to attachment/detachment of the antenna 110 is required.

In addition, the above-described problem may be equally applied to the case of performing state measurement for multiple chambers 10. Here, the multiple chambers 10 may be the same product manufactured through the same manufacturing process. However, even when they are the same product, the internal environments of the plurality of chambers may be slightly different due to tolerance. Therefore, even when the monitoring device 100 performs state measurement for a plurality of chambers that are all in the same state (e.g., idle state), the result values of the measured parameter sets may be calculated differently. Therefore, a method of correcting the error in state measurement in the plurality of chambers is also necessary.

In addition, in order to repeatedly perform state measurements for the plurality of chambers, since the monitoring device 100 must be continuously attached and detached to/from other chambers to perform state measurements, the correction of error due to the above-described attachment and detachment may occur equally for the plurality of chambers. Therefore, a method of correcting both of state measurement and attachment/detachment errors in different chambers is also required.

### 2. Embodiment 5-1: Method of Determining an Error Correction Function for Correcting a Measurement Error Caused by Repeatedly Attaching and Detaching a Monitoring Device 100 to/from a Chamber 10

In an embodiment according to the present disclosure, an error correction function is determined using a deep learning model (hereinafter, referred to as “learning model”), and state data measured by a monitoring device 100 is corrected using the determined error correction function, and then the corrected state data is compared with reference state data to calculate similarity, thereby generating the state similarity data.

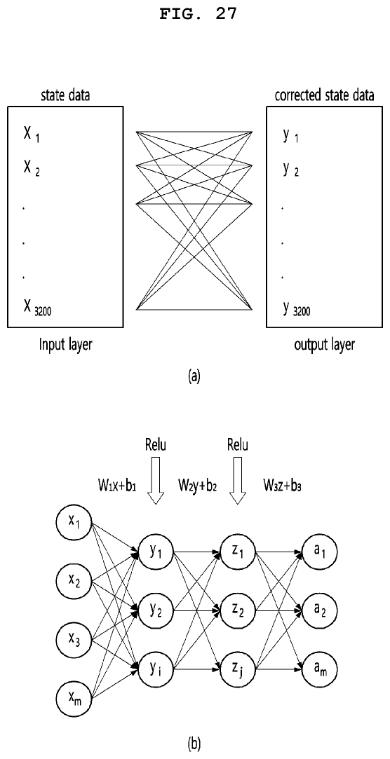

The learning model according to the embodiment of the present disclosure may use one of a single-layer perceptron neural network such as FIG. 27(a) and a multi-layer perceptron neural network such as FIG. 27(b). The single-layer perceptron neural network of FIG. 27(a) is a learning model that consists of an input layer and an output layer and has no other layers between the input layer and the output layer. The input data value input to each node of the input layer is converted/corrected into an output data value multiplied by at least one weight corresponding to each node. Herein, the input data value may also be converted/corrected into an output value that is multiplied by at least one weight and then added with a certain bias value.

The multilayer perceptron neural network of FIG. 27(b) is a deep learning model in which one or more other layers exist between the input layer and the output layer. FIG. 27(b) shows an example of a learning model in which two hidden layers exist between the input layer and the output layer.

The input data value input to each node of the input layer is converted into the first intermediate data calculated by multiplying at least one weight corresponding to each node of the first hidden layer (and then adding a bias value) and then input to the second hidden layer. The first intermediate data input to the second hidden layer is converted into the second intermediate data calculated by multiplying at least one weight corresponding to each node of the second hidden layer (and then adding a bias value) and then input to the output layer. The second intermediate data input to the output layer may be finally converted/corrected into the output value calculated by multiplying it with at least one weight corresponding to each node of the output layer (and then adding a bias value).

Hereinafter, the present disclosure is described assuming that the error correction function uses a single-layer perceptron neural network. However, a multilayer perceptron neural network may also be extended according to the idea of the present disclosure. For example, a plurality of W and b are configured as described below, and parameters of each of the plurality of W and b may be changed through the multilayer perceptron neural network.

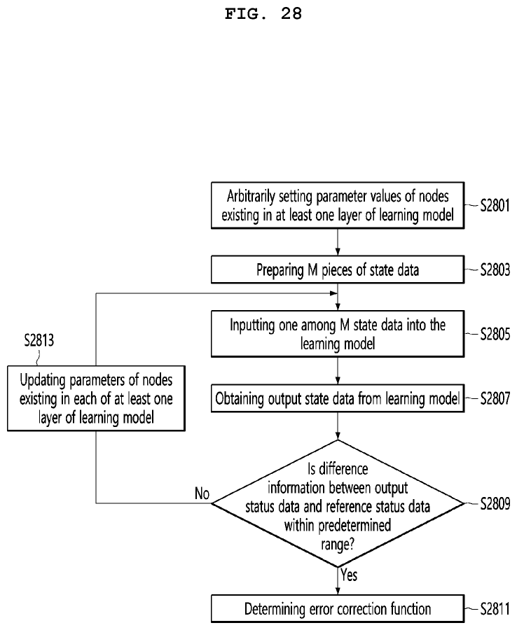

Hereinafter, referring to FIGS. 28 to 31, a method of determining an error correction function according to an embodiment of the present disclosure will be described.

Referring to FIG. 28, the monitoring device 100 may arbitrarily set parameter values of nodes existing in at least one layer of the learning model (S2801).

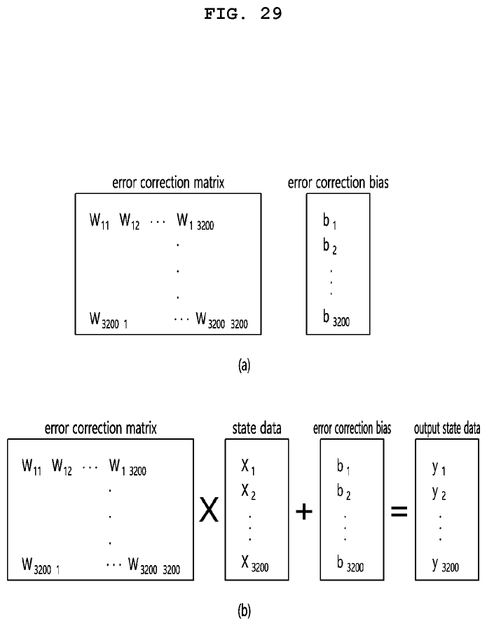

FIG. 29(a) shows an example of a learning model. Referring to FIG. 29(a), a learning model for correcting state data measured by a monitoring device 100 may include an error correction matrix and an error correction bias. The error correction matrix may include error correction parameters of w₁₁ to wₙₙ for n nodes. In addition, the error correction bias may include error correction parameters from b₁ to bₙ.

In step S2801, the monitoring device 100 may arbitrarily configure error correction parameters of w₁₁ to wₙₙ and error correction parameters of b₁ to bₙ.

The monitoring device 100 may measure state data while repeating attachment and detachment to/from the chamber 10 M times when the chamber 10 is in the same state (e.g., idle state), thereby preparing M pieces of state data (S2803).

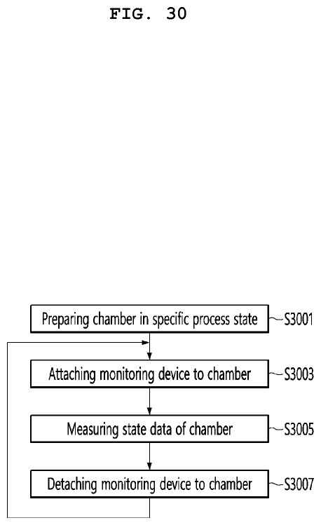

For example, referring to FIG. 30, a chamber 10 in a specific process state (e.g., idle state) is prepared (S3001), and a monitoring device 100 is attached to the outside of the chamber 10 (S3003). The monitoring device 100 may transmit a radio wave of a specific frequency range into the inside of the chamber 10 and receive reflected radio waves from the inside of the chamber 10. In addition, the monitoring device 100 may measure state data of the chamber 10 using the received radio wave and store the measured state data in the storage unit 150 (S3005). The monitoring device 100 is detached from the chamber 10 (S3007), and performs steps S3003 to S3007 repeatedly M times, so that the monitoring device 100 may prepare M pieces of state data.

The monitoring device 100 may input the first state data among the M pieces of state data into the learning model (S2805). The monitoring device 100 may obtain the first output state data based on the first state data from the learning model (S2807).

For example, referring to FIG. 29(b), each of the M pieces of state data measured by the monitoring device 100 may include n parameters, and each of the n parameters may be input to each of the n nodes of the learning model.

When each of the n parameters is input through each node, each of the n parameters is multiplied by the error correction parameters from w₁₁ to wₙₙ of the error correction matrix, and then added to the error correction parameters from b₁ to bₙ of the error correction bias, thereby outputting the output state data.

The monitoring device 100 calculates difference information between the first output state data and the reference state data. For example, the monitoring device 100 calculates difference values between n parameters included in the first output state data and n parameters included in the reference state data, which correspond to each other, and generate difference information based on the calculated difference values. For example, the difference information may be determined using a mean square error (MSE) of Equation 4 below.

$$MSE = \frac{1}{2} {\sum }_{i} {( {z}_{i} - {y}_{i} )}^{2} \qquad [ Equation 4 ]$$

wherein z indicates the reference state data, and y indicates the output state data. That is, i may have values from 1 to n, z1 is the first parameter value among the n parameters included in the reference state data, and zn is the nth parameter value among the n parameters included in the reference state data. Similarly, y1 is the first parameter value among the n parameters included in the output state data, and yn is the nth parameter value among the n parameters included in the output state data.

However, the method of using MSE and Equation 4 are only examples for producing difference information, and are not limited thereto. For example, in addition to Equation 4, the monitoring device 100 may determine difference information using the average error, which is the average of difference values, or the average standard error, which is the standard error value of difference values. As another example, the monitoring device 100 may determine difference information using the median error, which is the center value of difference values, or the mode error, which is the mode of difference values.

When the difference information is not included in a predetermined range (No), the monitoring device 100 may update the parameters of the nodes existing in each of at least one layer of the learning model (S2813). For example, When the monitoring device 100 does not include the MSE value in the predetermined range, the error correction parameters from w₁₁ to wₙₙ of the error correction matrix and the error correction parameters from b₁ to bₙ of the error correction bias may be updated.

For example, the monitoring device 100 may update the error correction parameters from w₁₁ to wₙₙ of the error correction matrix and the error correction parameters from b₁ to bₙ of the error correction bias by using the partial differential value of the difference information (e.g., MSE) as in Equation 5.

$$\begin{matrix}{w}_{11} \to {w}_{11} - {l}_{r} \frac{\partial MSE}{\partial {w}_{11}} \\ {b}_{1} \to {b}_{1} - lr \frac{\partial MSE}{\partial {b}_{1}}\end{matrix} \qquad [ Equation 5 ]$$

wherein lr (learning rate) indicates an adjustment rate for adjusting error correction parameters, which may be configured.

The monitoring device 100 returns to step S2805 to input the second state data among the M pieces of state data into the learning model with updated error correction parameters, and then proceeds to step S2109 to generate difference information between the second output state data and the reference state data. In addition, when the difference information is not included in the predetermined range, the monitoring device 100 updates the error correction parameters again based on the difference information (S2813), and then returns to step S2805 to inputs the third state data into the learning model.

In this way, the monitoring device 100 repeats steps S2805 to S2813 until the difference information is included in the predetermined range, and when the difference information is included in the predetermined range (Yes), determines the error correction function using the error correction matrix and error correction bias updated until then (S2811).

Alternatively, the monitoring device 100 may repeatedly perform steps S2805 to S2813 a predetermined number of times, and determine an error correction function by using the error correction matrix and error correction bias when a predetermined number of repetitions is completed. In this case, step S2809 may be omitted. In other words, the monitoring device 100 may repeatedly perform steps S2805, S2807, and S2813 by the predetermined number of repetitions, without determining whether the difference information is included within a predetermined range.

Alternatively, in the case that the monitoring device 100 repeatedly performs steps S2805 to S2813 by the predetermined number of repetitions and determines an error correction function using the error correction matrix and error correction bias when the predetermined number of repetitions is completed, when the difference information is included within a predetermined range before reaching the preset number of repetitions, the error correction function may be determined using the error correction matrix and error correction bias updated until then.

### 3. Embodiment 5-2: Method of Determining a Measurement Error Correction Function by Repeated Measurements on a Plurality of Chambers

As described above, even when the monitoring device 100 acquires state data for a plurality of chambers manufactured through the same manufacturing process in the same process state (e.g., idle state), different state data may be acquired due to tolerance, etc.

Therefore, in order to compensate for this measurement error, it is necessary to determine an error correction function for correcting the measurement error between the plurality of chambers.

Basically, the monitoring device 100 may determine an error compensation function for correcting the measurement error between the plurality of chambers through the same principle and process as Embodiment 5-1. In other words, in the description of Embodiment 5-1, it is appreciated that “measuring state data by repeating attachment and detachment for one chamber” may be easily replaced with “measuring state data for different chambers.” Therefore, the overlapping content with Embodiment 5-1 will be omitted.

In other words, the error correction function determination method described in FIG. 21 may be used in the present embodiment as well. However, only the process of preparing M pieces of state data in step S2803 may be different from Embodiment 5-1. In the description of Embodiment 5-1 described above, step S2803 was explained with reference to FIG. 30.

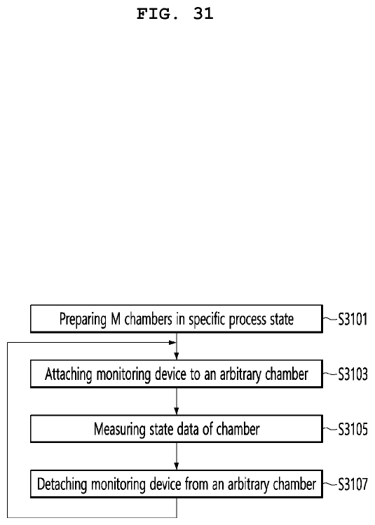

Meanwhile, in the present embodiment, the process of preparing M pieces of state data in step S2803 may be performed according to FIG. 31.

For example, referring to FIG. 31, in order to prepare M pieces of state data according to the present embodiment, M chambers in a specific process state (e.g., idle state) may be prepared (S3101).

The monitoring device 100 may be attached to the first chamber among the M chambers (S3103). The monitoring device 100 may transmit radio waves of a specific frequency range into the inside of the first chamber and receive reflected radio waves from the inside of the first chamber.

In addition, the monitoring device 100 may measure state data of the first chamber using the received radio waves and store the measured state data in the storage unit 150 (S3105). The monitoring device 100 is detached from the first chamber (S3107), and steps S3103 to S3107 are repeatedly performed M times, so that the monitoring device 100 may prepare M pieces of state data.

When the monitoring device 100 acquires the M pieces of state data according to the above-described method, the monitoring device 100 may repeatedly perform steps S2805 to S2813 of FIG. 28 until the difference information between the output state data output from the learning model and the reference state data is included within a predetermined range (S2811), thereby determining an error correction function.

Since the method of determining the error correction function by the monitoring device 100, that is, the method of performing steps S2805 to S2813 and S2811 in this embodiment is the same as that described in Embodiment 5-1, descriptions thereof are omitted.

Meanwhile, when the number of chambers that are the subjects of learning in Embodiment 5-2 is sufficiently large, it may also be used to correct measurement errors in chambers other than the chambers that are the subjects of learning.

### 4. Embodiment 5-3: Generating an Error Correction Function for Attachment/Detachment for Each of the Chambers to Generate an Error Correction Function Capable of Simultaneous Application to Embodiment 5-1 and Embodiment 5-2

Meanwhile, in order to create an error correction function that may simultaneously correct the attachment/detachment measurement error in Embodiment 5-1 and the measurement error in different chambers in Embodiment 5-2, M pieces of state data may be secured as follows.

First, P chambers may be prepared. Here, all P chambers may be products of the same model produced through the same process. However, as described above, process errors may exist. In addition, all P chambers for collecting M pieces of state data are in the same first process state (e.g., idle state). The monitoring device 100 is attached to the first chamber among the P chambers, to measure the state data of the first chamber. In addition, while the first chamber is in the same first process state, Q pieces of state data for the first chamber may be measured while repeatedly attaching and detaching the monitoring device 100 to the first chamber Q times.

Next, the monitoring device 100 is attached to the second chamber among the P chambers, to measure the state data of the second chamber. Then, while the second chamber is in the same first process state, the monitoring device 100 may measure Q pieces of state data for the second chamber while repeating attachment/detachment to the second chamber Q times.

As described above, the monitoring device 100 may obtain Q pieces of state data for each of the P chambers. That is, in the manner described above, the monitoring device 100 may collect P×Q pieces of state data. Here, P×Q=M.

When the monitoring device 100 obtains M pieces of state data according to the above-described method, the monitoring device 100 repeatedly performs S2805 to S2813 of FIG. 28 until the difference information between the output state data output from the learning model and the reference state data is included within a predetermined range, to determine an error correction function (S2811).

Since the method of determining the error correction function by the monitoring device 100, i.e., the method of performing S2805 to S2813 and S2811 in this embodiment is the same as described in Embodiment 5-1, descriptions thereof is omitted.

### 5. Embodiment 5-4: Method of Correcting an Error Using an Error Correction Function

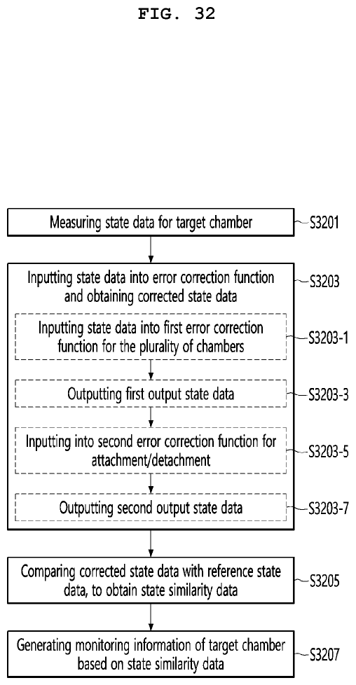

Now, a method for correcting state data using at least one error correction function generated using at least one of Embodiment 5-1, Embodiment 5-2, and Embodiment 5-3 will be described with reference to FIG. 32.

The monitoring device 100 is attached to the outside or inside of a target chamber. Then the monitoring device 100 may transmit radio waves of a specific frequency range into the inside of the target chamber and receive reflected radio waves from the inside of the target chamber. The monitoring device 100 may measure state data (e.g., a set of S parameters as a response to each frequency) using the received radio wave (S3201).

The monitoring device 100 may input state data into an error correction function and obtain corrected state data from the error correction function (S3203).

For example, the error correction function for correcting the state data may use at least one of the error correction functions that may be generated using at least one of Embodiment 5-1, Embodiment 5-2, and Embodiment 5-3.

As a specific example, the monitoring device 100 may use one of the following four methods to obtain the corrected state data.
(1) In order to correct an error due to the chamber to which the monitoring device 100 is attached, the state data may be input into the first error correction function generated by Embodiment 5-2, and the corrected state data may be obtained from the first error correction function.
(2) In order to correct an error due to the attachment position of the monitoring device 100, the state data may be input into the second error correction function generated by Embodiment 5-1, and the corrected state data may be obtained from the second error correction function.
(3) In order to correct both an error due to the attachment position of the monitoring device 100 and an error due to the chamber to which the monitoring device 100 is attached, the state data may be input into the third error correction function generated by Embodiment 5-3, and the corrected state data may be obtained from the third error correction function.
(4) As another example, in order to correct both an error due to the attachment position of the monitoring device 100 and an error due to the chamber to which the monitoring device 100 is attached, the first error correction function generated by Embodiment 5-1 and the second error correction function generated by Embodiment 5-2 may be used.

For example, referring to FIG. 21, the monitoring device 100 inputs the state data into the first error correction function generated by Embodiment 5-2 to correct the measurement error due to tolerance of the plurality of chambers (S3203-1), thereby obtaining the first output state data from the first error correction function (S3203-3). In addition, the monitoring device 100 inputs the first output state data into the second error correction function generated by Embodiment 5-1 to correct the measurement error due to the attachment/detachment (S3203-5), thereby obtaining the second output state data from the second error correction function (S3203-7). The monitoring device 100 may determine the second output state data as the final corrected state data.

Herein, it is not allowed to first obtain the second output state data by inputting the state data measured by the monitoring device 100 into the second error correction function, and obtain the first output state data by inputting the second output state data into the first error correction function. This is because first correcting the process error between the chambers and then correcting the attachment/detachment for one chamber may further increase the correction accuracy of the measurement error.

The monitoring device 100 may obtain similarity by comparing the corrected state data obtained by any one of (1) to (4) in the above-described step S3203 with the reference state data, and may obtain state similarity data using the obtained similarity (S3205).

The monitoring device 100 may generate monitoring information of the target chamber based on the state similarity data (S3207).

Herein, steps S3205 and S3207 may be performed based on Embodiment 3. For example, at least one error correction function is generated according to at least one of the embodiments described in Embodiment 5, and the state data of the target chamber measured by the monitoring device 100 may be input into the error correction function to obtain the corrected state data. In addition, when performing at least one of Embodiment 3-1, Embodiment 3-2, and Embodiment 3-3, the monitoring device 100 may perform at least one of Embodiment 3-1, Embodiment 3-2, and Embodiment 3-3 by using the state data described in Embodiment 3-1, Embodiment 3-2, and Embodiment 3-3 as the corrected state data.

In other words, it is possible to correct the state data measured by the monitoring device 100 by using at least one of Embodiment 5-1 to Embodiment 5-3, and it is possible to determine whether it is operating normally or to predict the time point of abnormal operation for the target chamber by using the corrected state data based on at least one of Embodiment 3-1 to Embodiment 3-3.

That is, at least one of Embodiment 5-1 to Embodiment 5-3 and at least one of Embodiment 3-1 to Embodiment 3-3 may be applied together in sequence, in which the “state data” of Embodiment 3-1 to Embodiment 3-3 should be understood as the “corrected state data” of Embodiment 5-1 to Embodiment 5-3.

### 6. Experimental Data

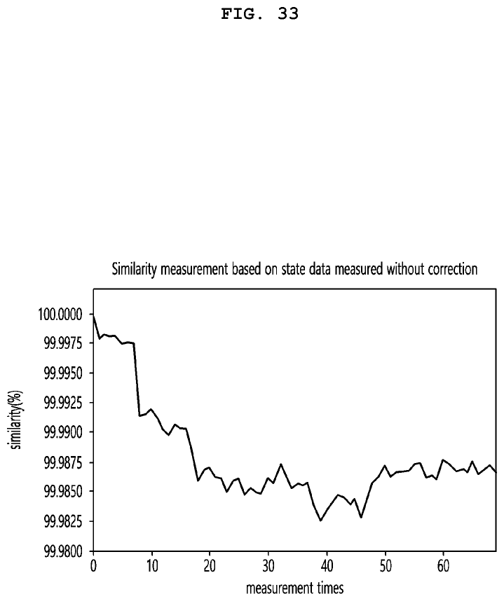

FIGS. 33 to 36 show that when state data is measured while repeatedly attaching and detaching a monitoring device 100 to/from a chamber 10 without correction in Embodiment 5-1, an error correction function is generated through a learning model, and then the measurement error of the state data measured is corrected by the generated error correction function.

In FIG. 33, a vertical axis indicates the value of the state similarity data, and a horizontal axis indicates the number of repeated attachment and detachment.

FGIS. 33 and 34 are graphs representing the similarity calculated by measuring state data while repeatedly attaching and detaching the monitoring device 100 to/from the chamber 10 without correction and comparing the corresponding state data with the reference state data, and the state similarity data based on it, in which the same graph is displayed on different scales. Herein, the chamber 10 is always in the same state (e.g., idle state).

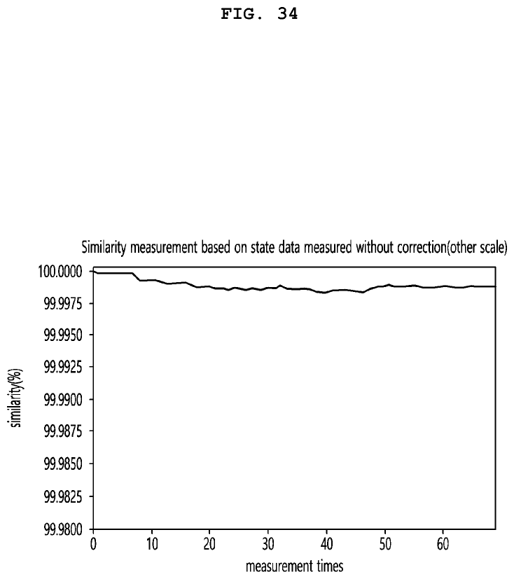

As may be seen in FIG. 33 and FIG. 34, it may be noted that the state similarity data is different simply by attaching or detaching the monitoring device 100 to/from the chamber 10.

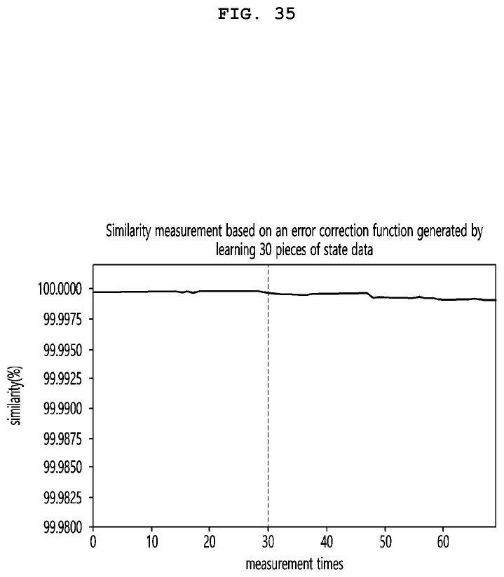

FIG. 35 is a graph showing the state similarity data obtained based on the corrected state data after correcting the state data measured by the monitoring device 100 using an error correction function generated by sequentially inputting 30 pieces of state similarity data into the learning model. FIG. 35 has the same Y-axis scale as FIG. 33.

With respect to FIG. 35, it may be seen that the state similarity data is measured more uniformly than FIG. 33.

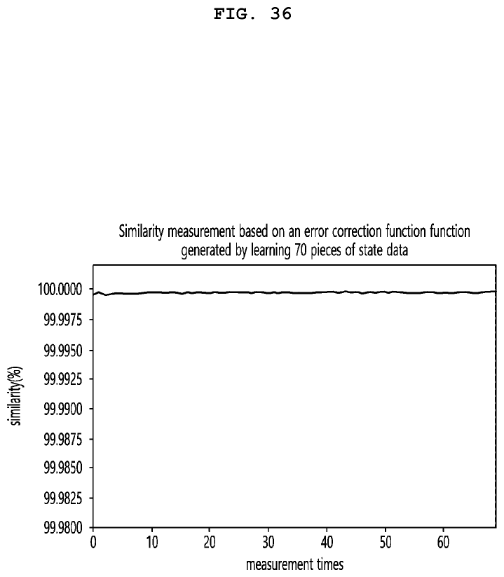

FIG. 36 is a graph of the state similarity data obtained based on the corrected state data after correcting the state data measured by the monitoring device 100 using an error correction function generated by sequentially inputting 70 pieces of state similarity data into the learning model.

With respect to FIG. 36, it may be seen that the state similarity data is more uniform than FIGS. 33 and 35.

That is, the more the number of state data that are trained through the learning model, the more accurately the measurement error due to detachment is corrected by the error correction function.

Similarly, in Embodiment 5-2 and Embodiment 5-3, it will be appreciated by a person skilled in the art that as the number of state data that are trained through the learning model is larger, the measurement errors due to a plurality of chambers are more accurately corrected by the error correction function.

### [Monitoring System]

A monitoring system including one or more of the aforementioned monitoring devices may be provided. The monitoring system may be installed in a process equipment including one or more chambers.

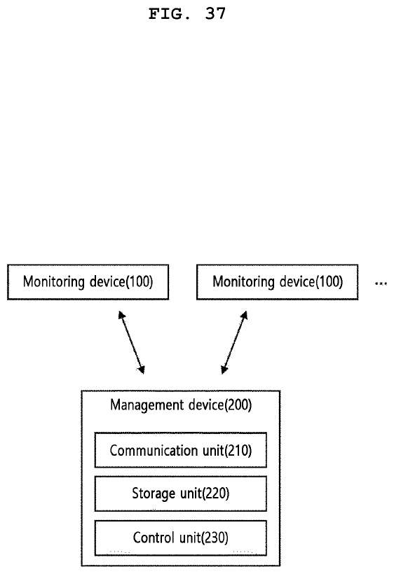

FIG. 37 is a block diagram illustrating a monitoring system according to an embodiment.

Referring to FIG. 37, the monitoring system may include one or more monitoring devices 100 and a management device 200. Here, a duplicate description of the monitoring device 100 will be omitted.

The monitoring system may include a management device 200. The management device 200 may manage the monitoring device 100.

The management device 200 may include a communication unit 210, a storage unit 220, and a control unit 230.

The management device 200 may perform communication with the outside through the communication unit 210. For example, the management device 200 may obtain monitoring information from the monitoring device 100 through the communication unit 210. As another example, the management device 200 may transmit the monitoring information to an external device such as process equipment or a Fab through the communication unit 210. Duplicate descriptions of parts similar to the communication unit 210 of the monitoring device 100 are omitted.

The management device 200 may store various data and programs in the storage unit 220. For example, the storage unit 220 may store monitoring information. AS another example, the storage unit 220 may store reference state data. Duplicate descriptions of parts similar to the storage unit 220 of the monitoring device 100 are omitted.

The control unit 230 may perform processing and calculation of various information within the management device 200. The control unit 230 may control other components that constitute the management device 200. Duplicate descriptions of parts similar to the control unit 230 of the monitoring device 100 are omitted.

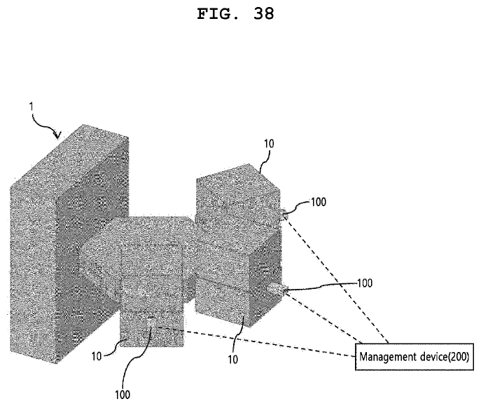

FIG. 38 is a schematic diagram illustrating a monitoring system installed in process equipment according to an embodiment, in which the monitoring device is an integrated unit. Referring to FIG. 38, a monitoring device 100 may be mounted in each chamber 10 of the process equipment 1. The monitoring device 100 may generate state data of the chamber 10 in which it is mounted. The monitoring device 100 may generate monitoring information based on the state data. Alternatively, the monitoring device 100 may transmit state data to the management device 200, and the management device 200 may generate monitoring information.

Meanwhile, an error correction function may be created using a plurality of monitoring devices 100. Even when a plurality of monitoring devices 100 measure one chamber, since measurement errors may occur due to tolerances or circuit characteristics between the plurality of monitoring devices 100, there may be a need to correct such measurement errors.

For example, when performing Embodiment 5-1 by exchanging different monitoring devices 100 for each attachment/detachment (or every certain number of attachment/detachments (e.g., 1000 times)) to/from the chamber, errors of the plurality of monitoring devices 100 may be corrected. In addition, when the number of the monitoring devices is sufficiently large, errors of monitoring devices other than the plurality of monitoring devices 100 may be also corrected. For example, when the number of monitoring devices 100 is R and the number of times each monitoring device 100 is attached or detached is S, R×S pieces of state data may be prepared when attaching or detaching each of the monitoring devices 100 to/from the chamber. Accordingly, errors due to attachment or detachment of the plurality of monitoring devices 100 may be corrected using R×S pieces of state data.

In addition, as described in Embodiment 5-2, it is possible to perform error correction for the plurality of monitoring devices 100 and the plurality of chambers, by measuring status similarity data for the plurality of chambers to create the data set using the plurality of monitoring devices 100. For example, when the number of monitoring devices 100 is R and the number of chambers is T, R×T pieces of state data may be prepared by measuring the state data for S chambers 10 using each of the monitoring devices 100. Accordingly, the error correction for a plurality of chambers of a plurality of monitoring devices 100 may be performed using R×T pieces of state data.

In addition, as described in Embodiment 5-3, the data set may be generated for different chambers by exchanging the plurality of monitoring devices 100 while attaching and detaching them to/from one chamber, so that an error correction function for the plurality of monitoring devices 100 and the plurality of chambers may be generated, which results in error correction. For example, when the number of monitoring devices 100 is R, the number of chambers 10 is T, and the number of times one monitoring device 100 is attached and detached to/from one chamber 10 is S, R×T×S pieces of state data may be prepared. Accordingly, errors due to the plurality of chambers of the plurality of monitoring devices 100 may be corrected using R×T×S pieces of state data.

Herein, when the number of the plurality of monitoring devices 100 and/or the plurality of chambers is sufficiently large, the measurement errors for monitoring devices and chambers, other than the plurality of monitoring devices 100 and/or the plurality of chambers may also be corrected.

### Implementation Examples of Embodiments

Meanwhile, as mentioned in the description of the above-described embodiments, the above-described embodiments may each be applied independently, but at least one of the above-described embodiments may also be implemented in combination.

For example, after generating reference state data according to Embodiment 1, an error correction function may be generated according to Embodiment 5, so that state data measured by the monitoring device 100 may be substituted into the error correction function to obtain corrected state data. In addition, the monitoring device 100 may utilize the corrected state data as state data of Embodiment 3 or Embodiment 4, and generate the state similarity pattern and a state similarity graph using Embodiment 2. In addition, the monitoring device 100 may determine whether the target chamber is operating normally or predict the time point of abnormal operation according to Embodiment 3 or Embodiment 4.

Meanwhile, based on the foregoing, the error correction function created for the plurality of monitoring devices according to the monitoring system described in FIG. 27 and FIG. 28 may also correct measurement errors as a combination of Embodiment 1 to Embodiment 5, determine whether the target chamber is operating normally, and predict the time point of abnormal operation.

A method according to an embodiment may be performed by processing logic including hardware, firmware, software, or a combination thereof. A method according to an embodiment may be performed by a processor for executing code stored in a non-transitory computer-readable medium. Examples of the non-transitory computer-readable medium include magnetic media such as hard disks, floppy disks, and magnetic tapes; optical media such as CD-ROMs, and DVD-ROMs; magneto-optical media such as floptical disks; and hardware devices, such as ROM, RAM, and flash memory, which are particularly structured to store and execute program instructions.

Although the present disclosure has been described above with reference to embodiments, the present disclosure is not limited thereto. It will be apparent to those skilled in the art to which this application belongs that various changes or modifications may be made the spirit and scope of the present disclosure, and that such changes or modifications fall within the scope of the appended patent claims.

What is claimed is:

1. A method of monitoring a state of a chamber by a chamber monitoring apparatus, wherein a process cycle including a plurality of processes is performed one or more times in the chamber, the method comprising:
obtaining a reference state data for monitoring the state of the chamber, wherein the reference state data is a first reference state data of the chamber measured in IDLE duration of the chamber or a second reference state data of the chamber measured in a duration corresponding to one of the plurality of processes;
transmitting radio waves in a specific frequency range into an inside of the chamber M times and receiving reflected radio waves from the inside of the chamber M times, wherein Mis natural number and is equal or larger than 2;
generating a plurality of third state data by measuring the state of the chamber based on the received radio waves M times;
calculating similarities between each of the plurality of third state data and the reference state data and obtaining a plurality of pieces of state similarity data using the similarities;
obtaining a plurality of state similarity patterns configured in unit of the process cycle by matching process duration data for durations in which each of the plurality of processes is performed and the plurality of pieces of state similarity data; and
determining whether the chamber is performed in a normal operation or predicting when the chamber will be entered in an abnormal operation using two or more state similarity patterns among the plurality of state similarity patterns.

2. The method of claim 1, wherein the predicting when the chamber will be entered in the abnormal operation comprising:
selecting two or more state similarity data among the plurality of pieces of state similarity data, wherein a state similarity data corresponding to a first process is selected in each of the plurality of state similarity patterns;
determining a function for predicting the abnormal operation based on the two or more state similarity data, wherein the function is determined based on a time variable; and
predicting, as a time of the abnormal operation of the chamber, a first time that a result value of the function calculated according to the time variable is equal to or smaller than a preconfigured similarity threshold.

3. The method of claim 2, wherein the predicting when the chamber will be entered in the abnormal operation is repeatedly performed at each time when the state similarity pattern is additionally obtained.

4. The method of claim 1, wherein the determining whether the chamber is performed in the normal operation comprising:
selecting a first state similarity pattern lastly obtained among the plurality of state similarity patterns;
selecting a second state similarity pattern, different the first state similarity pattern, among the plurality of state similarity patterns;
calculating difference values between the first state similarity pattern and the second state similarity pattern according to each process and a corresponding time in the each process; and
determining that the chamber is operated in abnormal in a process corresponding to a difference value exceeding a preconfigured similarity threshold among the difference values.

5. The method of claim 4, wherein the determining whether the chamber is performed in the normal operation comprising:
determining the preconfigured similarity threshold according to an interval between the first state similarity pattern and the second state similarity pattern within the plurality of state similarity patterns.

6. The method of claim 4, wherein the calculating difference values between the first state similarity pattern and the second state similarity pattern comprising:
adjusting state similarity data of the first state similarity pattern based on state similarity data of the second state similarity pattern; and
calculating difference values between the adjusted state similarity data of the first state similarity pattern and the state similarity data of the second state similarity pattern.

7. The method of claim 6, wherein the adjusting state similarity data of the first state similarity pattern comprising:
selecting two or more state similarity data among the plurality of pieces of state similarity data, wherein a state similarity data corresponding to a first process is selected in each of the plurality of state similarity patterns;
determining a function for predicting the abnormal operation based on the two or more state similarity data, wherein the function is determined based on a time variable; and
adjusting the state similarity data of the first state similarity pattern based on the function and the state similarity data of the second state similarity pattern.

8. The method of claim 4, wherein the second state similarity pattern is first obtained state similarity pattern among the plurality of state similarity patterns.

9. The method of claim 1, wherein the obtaining a reference state data comprising:
transmitting radio waves in the specific frequency range into the inside of the chamber N times and receiving reflected radio waves in the inside of the chamber N times, wherein M is natural number in the IDLE duration of the chamber or in the duration corresponding to one of the plurality of processes,
generating a plurality of fourth state data by measuring the state of the chamber N times based on the received radio waves N times; and
obtaining the reference state data based on the plurality of fourth state data.

10. A chamber monitoring apparatus of monitoring a state of the chamber, wherein a process cycle including a plurality of processes is performed one or more times in the chamber,
the chamber monitoring apparatus comprising:
an antenna configured to transmit radio waves in a specific frequency range into an inside of the chamber and receive reflected radio waves from the inside of the chamber;
a bracket configured to fix the antenna to an outside of the chamber;
a signal processor configured to apply an electrical signal to the antenna and obtain an electrical signal from the antenna; and
a controller configured to control the signal processor and generate a state data of the chamber based on the obtained electrical signal,
wherein the controller is configured to:
obtain a reference state data for monitoring the state of the chamber, wherein the reference state data is a first reference state data of the chamber measured in IDLE duration of the chamber or a second reference state data of the chamber measured in a duration corresponding to one of the plurality of processes,
control the signal processor, such that the antenna transmits radio waves M times and receive radio waves M times, to obtain electrical signals according to the received radio waves, wherein M is natural number and is equal or larger than 2,
generate a plurality of third state data by measuring the state of the chamber based on the electrical signals,
calculate similarities between each of the plurality of third state data and the reference state data and obtain a plurality of pieces of state similarity data using the similarities,
obtain a plurality of state similarity patterns configured in unit of the process cycle by matching a process duration data for durations in which each of the plurality of processes is performed and the plurality of pieces of state similarity data, and
determine whether the chamber is performed in a normal operation or predicting when the chamber will be entered in an abnormal operation using two or more state similarity patterns among the plurality of state similarity patterns.

11. The chamber monitoring apparatus of claim 10, wherein the controller is configured to:
select two or more state similarity data among the plurality of pieces of state similarity data, wherein a state similarity data corresponding to a first process is selected in each of the plurality of state similarity patterns,
determine a function for predicting the abnormal operation based on the two or more state similarity data, wherein the function is determined based on a time variable, and
predict, as a time of the abnormal operation of the chamber, a first time that a result value of the function calculated according to the time variable is equal to or smaller than a preconfigured similarity threshold.

12. The chamber monitoring apparatus of claim 11, wherein the controller is configured to:
repeatedly predict when the chamber will be entered in the abnormal operation at each time when the state similarity pattern is additionally obtained.

13. The chamber monitoring apparatus of claim 10, wherein the controller is configured to:
select a first state similarity pattern lastly obtained among the plurality of state similarity patterns,
select a second state similarity pattern, different the first state similarity pattern, among the plurality of state similarity patterns,
calculate difference values between the first state similarity pattern and the second state similarity pattern according to each process and a corresponding time in the each process, and
determine that the chamber is operated in abnormal in a process corresponding to a difference value exceeding a preconfigured similarity threshold among the difference values.

14. The chamber monitoring apparatus of claim 13, wherein the controller is configured to:
determine the preconfigured similarity threshold according to an interval between the first state similarity pattern and the second state similarity pattern within the plurality of state similarity patterns.

15. The chamber monitoring apparatus of claim 13, wherein the controller is configured to:
adjust state similarity data of the first state similarity pattern based on state similarity data of the second state similarity pattern, and
calculate difference values between the adjusted state similarity data of the first state similarity pattern and the state similarity data of the second state similarity pattern.

16. The chamber monitoring apparatus of claim 15, wherein the controller is configured to:
select two or more state similarity data among the plurality of pieces of state similarity data, wherein a state similarity data corresponding to a first process is selected in each of the plurality of state similarity patterns,
determine a function for predicting the abnormal operation based on the two or more state similarity data, wherein the function is determined based on a time variable, and
adjust the state similarity data of the first state similarity pattern based on the function and the state similarity data of the second state similarity pattern.

17. The chamber monitoring apparatus of claim 13, wherein the second state similarity pattern is first obtained state similarity pattern among the plurality of state similarity patterns.

18. The chamber monitoring apparatus of claim 10, wherein the controller is configured to:
transmit radio waves in a specific frequency range into the inside of the chamber N times and receiving reflected radio waves in the inside of the chamber N times, wherein M is natural number in the IDLE duration of the chamber or in the duration corresponding to one of the plurality of processes,
generate a plurality of fourth state data by measuring the state of the chamber N times based on the received radio waves N times, and
obtain the reference state data based on the plurality of fourth state data.
